(19) United States
(12) Patent Application Publication
(10) Pub. No.: US 2026/0123028 A1
(43) Pub. Date: Apr. 30, 2026

(54) SEMICONDUCTOR DEVICE

(71) Applicant: FUJI ELECTRIC CO., LTD., Kanagawa (JP)

(72) Inventors: Tohru SHIRAKAWA, Matsumoto-city (JP); Yasunori AGATA, Matsumoto-city (JP); Yuuki ODA, Matsumoto-city (JP); Toshiki SUZUKI, Matsumoto-city (JP)

(21) Appl. No.: 19/433,068

(22) Filed: Dec. 26, 2025

Related U.S. Application Data
(63) Continuation of application No. PCT/JP2025/002861, filed on Jan. 29, 2025.

(30) Foreign Application Priority Data
Jan. 30, 2024 (JP) 2024-011488
Sep. 30, 2024 (JP) 2024-170760

(51) Int. Cl. H10D 84/00; H10D 8/00; H10D 12/00; H10D 62/10; H10D 62/53; H10D 62/60

(52) U.S. Cl. CPC H10D 84/161; H10D 8/422; H10D 12/481; H10D 62/107; H10D 62/126; H10D 62/60; H10D 62/53

(57) ABSTRACT

Provided is a semiconductor device in which the first cathode region and the second cathode region are provided alternately in the first direction, one or more first cathode regions are provided in a second direction that intersects the first direction, and a length Lx between both ends of the one or more first cathode regions in the second direction and a width Dyn of one first cathode region in the first direction satisfy a following expression: 0.001<Dyn/Lx≤0.1.

The contents of the following patent application(s) are incorporated herein by reference:
NO. 2024-011488 filed in JP on Jan. 30, 2024
NO. 2024-170760 filed in JP on Sep. 30, 2024
NO. PCT/JP2025/002861 filed in WO on Jan. 29, 2025.

### BACKGROUND

### 1. Technical Field

The present invention relates to a semiconductor device.

### 2. Related Art

Conventionally, as cathode regions of diodes, structures in which N type and P type regions are mixed have been known (for example, see Patent Document 1 and 2).
Patent Document 1: International Publication No. WO 2019/176810
Patent Document 2: Japanese Patent No. 7334407

### BRIEF DESCRIPTION OF THE DRAWINGS

FIG. 1 is a top plan view illustrating an example of a semiconductor device 100 according to one embodiment of the present invention.

FIG. 2 is an enlarged view of a region D in FIG. 1.

FIG. 3 shows an example of a cross-section e-e in FIG. 2.

FIG. 4 shows an exemplary arrangement of a first cathode region 81 and a second cathode region 82 on a lower surface 23 of a semiconductor substrate 10.

FIG. 5 shows a relationship between a ratio between a length Lx and a width Dyn and a reverse recovery loss Err.

FIG. 6 shows a relationship between a forward voltage Vf and a reverse recovery loss Err of a diode portion 80 when the width Dyn and the width Dyp are varied.

FIG. 7 shows another exemplary arrangement of the first cathode region 81 and the second cathode region 82.

FIG. 8 shows another exemplary arrangement of the first cathode region 81 and the second cathode region 82 on the lower surface 23 of the semiconductor substrate 10.

FIG. 9 shows another exemplary arrangement of the first cathode region 81 and the second cathode region 82 on the lower surface 23 of the semiconductor substrate 10.

FIG. 10 shows another exemplary arrangement of the first cathode region 81 and the second cathode region 82 on the lower surface 23 of the semiconductor substrate 10.

FIG. 11 shows a time waveform of an anodic current during reverse recovery.

FIG. 12 shows a relationship between the forward voltage Vf and the reverse recovery loss Err of the diode portion 80 when the width Dyn and the width Dyp are varied.

FIG. 13 shows a relationship between the forward voltage of the diode portion 80 and an anode-cathode current when the width Dyp is varied.

FIG. 14 shows a relationship between the forward voltage Vf and a forward surge current withstand capability (IFSM withstand capability) of the diode portion 80 when the width Dyp is varied.

FIG. 15 shows an example of a cross-section A-A shown in FIG. 4.

FIG. 16 shows an example of a shape of the first cathode region 81 in a top view.

FIG. 17 shows another example of a cross-section Y-Z.

FIG. 18 shows an example of chemical concentration distribution of phosphorus and boron in the first cathode region 81, the second cathode region 82, and the third cathode region 84.

FIG. 19 shows an example of the doping concentration distribution in the line B-B in FIG. 17.

FIG. 20 shows an example of the doping concentration distribution in the line C-C in FIG. 17.

FIG. 21 shows another example of the cross-section Y-Z.

FIG. 22 shows another example of the cross-section Y-Z.

FIG. 23 shows another example of the cross-section Y-Z.

FIG. 24 shows another example of the cross-section Y-Z.

FIG. 25 shows another example of the cross-section Y-Z.

FIG. 26 shows another example of the cross-section Y-Z.

FIG. 27 shows an example of a cross-section G-G in FIG. 1.

FIG. 28 shows another example of the cross-section G-G.

FIG. 29 shows a relationship between the forward voltage Vf and the reverse recovery loss Err of the diode portion 80.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in implementation of a semiconductor device.

In the present specification, technical matters may be described by using orthogonal coordinate axes of an X-axis, a Y-axis, and a Z-axis. The orthogonal coordinate axes merely specify relative positions of components, and do not limit a particular direction. For example, the Z-axis is not limited to indicate a height direction with respect to the ground. It is to be noted that a +Z-axis direction and a −Z-axis direction are directions opposite to each other. When the Z-axis direction is described without describing a sign, it means that the direction is parallel to the +Z-axis and the −Z-axis.

In the present specification, orthogonal axes parallel to the upper surface and the lower surface of the semiconductor substrate are referred to as the X-axis and the Y-axis. In addition, an axis perpendicular to the upper surface and the lower surface of the semiconductor substrate is referred to as the Z-axis. In the present specification, the direction of the Z-axis may be referred to as the depth direction. In addition, in the present specification, a direction parallel to the upper surface and the lower surface of the semiconductor substrate may be referred to as a horizontal direction, including an X-axis direction and a Y-axis direction.

region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. The hydrogen donor may be a donor obtained by the combination of at least a vacancy (V) and hydrogen (H). Alternatively, interstitial Si—H in which interstitial silicon (Si-i) in a silicon semiconductor is attached to hydrogen, and CiOi-H in which interstitial carbon (Ci) is attached to interstitial oxygen (Oi) and hydrogen also function as a donor which supplies electrons. In the present specification, the VOH defect, the CiOi-H, or the interstitial Si—H may be referred to as the hydrogen donor.

In the semiconductor substrate in the present specification, bulk donors of the N type are distributed throughout. The bulk donor is a dopant donor substantially uniformly contained in an ingot during the manufacture of the ingot from which the semiconductor substrate is made. The bulk donor in the present example is an element other than hydrogen. The bulk donor dopant is, for example, phosphorous, antimony, arsenic, selenium, or sulfur, but the invention is not limited to these. The bulk donor in the present example is phosphorous. The bulk donor is also contained in a region of the P type. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in the present example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. In addition, as the semiconductor substrate, a non-doped substrate not containing a dopant such as phosphorous may be used. In that case, the bulk donor concentration (DO) of the non-doped substrate is, for example, from 1×10¹⁰/cm³ or more and to 5×10¹²/cm³ or less. The bulk donor concentration (D0) of the non-doped substrate is preferably 1×10¹¹/cm³ or more. The bulk donor concentration (D0) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P-type or an N-type means a lower doping concentration than that of the P type or the N type. In addition, in the present specification, a description of a P++ type or an N++ type means a higher doping concentration than that of the P+ type or the N+ type. In the present specification, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). In addition, a carrier concentration measured by spreading resistance profiling (SRP method) may be set as the net doping concentration. The carrier concentration measured by the CV profiling or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or/cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in the carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. The semiconductor substrate may be silicon, silicon carbide, gallium nitride, diamond, or gallium oxide.

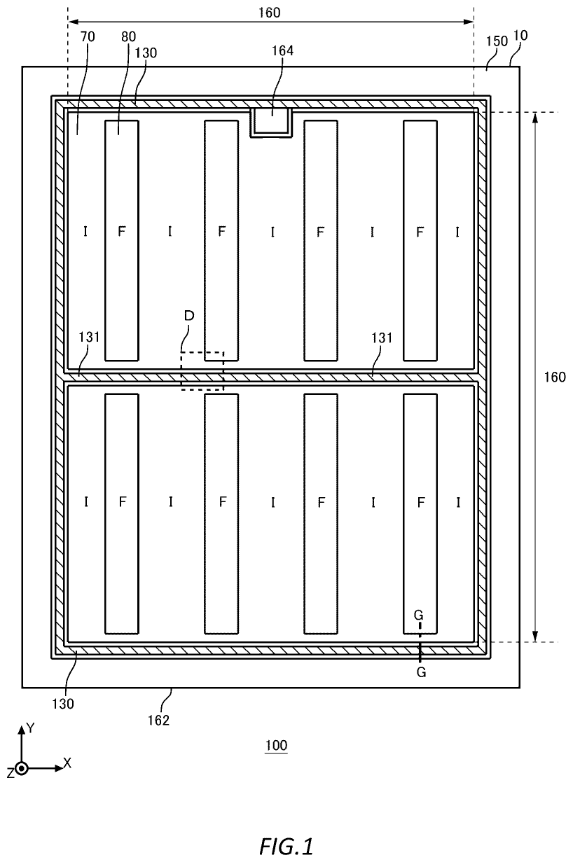

FIG. 1 is a top plan view illustrating an example of a semiconductor device 100 according to one embodiment of the present invention. FIG. 1 illustrates a position at which each member is projected on an upper surface of a semiconductor substrate 10. FIG. 1 illustrates only some members of the semiconductor device 100, and illustration of some members is omitted.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side. The semiconductor substrate 10 in the present example has two sets of end sides 162 opposite to each other in a top view. In FIG. 1, the X-axis and the Y-axis are parallel to any of the end sides 162. In addition, the Z-axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but is omitted in FIG. 1. The active portion 160 may refer to a region which overlaps with the emitter electrode in the top view. In addition, a region sandwiched between active portions 160 in the top view may also be included in the active portion 160.

A diode portion 80 which includes a diode element such as a freewheeling diode (FWD) is provided in the active portion 160. A transistor portion 70 which includes a transistor device such as an IGBT (Insulated Gate Bipolar Transistor) may further be provided in the active portion 160. In the example shown in FIG. 1, the transistor portions 70 and the diode portions 80 are alternately arranged along a predetermined array direction (the X-axis direction in the present example) at the upper surface of the semiconductor substrate 10. The semiconductor device 100 in the present example is a reverse conduction type IGBT (RC-IGBT). The transistor portion 70 and the diode portion 80 are connected in anti-parallel to each other. That is, an emitter of a transistor portion 70 and an anode of a diode portion 80 are electrically connected, and a collector of the transistor portion 70 and a cathode of the diode portion 80 are electrically connected.

In FIG. 1, a region where the transistor portion 70 is arranged is indicated by a symbol “I”, and a region where the diode portion 80 is arranged is indicated by a symbol “F”. In the present specification, a direction perpendicular to the array direction in a top view may be referred to as an extending direction (the Y-axis direction in FIG. 1). The transistor portion 70 and the diode portion 80 may each have a longitudinal length in an extension direction. That is, a length of the transistor portion 70 in the Y-axis direction is larger than its width in the X-axis direction. Similarly, a length of the diode portion 80 in the Y-axis direction is larger than its width in the X-axis direction. The extending directions of the transistor portion 70 and the diode portion 80, and a longitudinal direction of each trench portion described below may be the same.

The diode portion 80 has a first cathode region of N+ type and a second cathode region of P type in a region that is in contact with the lower surface of the semiconductor substrate 10. In the present specification, a repetition structure that includes the first cathode region and the second cathode region is periodically arranged in a predetermined direction on the lower surface of the semiconductor substrate 10. A region in which the first cathode region or the second cathode region is arranged is referred to as the diode portion 80. On the lower surface of the semiconductor substrate 10, a collector region of the P type may be provided in a region other than the diode portion 80.

The transistor portion 70 has a collector region of the P type in a region in contact with the lower surface of the semiconductor substrate 10. In addition, in the transistor portion 70, an emitter region of the N type, a base region of the P type, and a gate structure having a gate conductive portion and a gate dielectric film are periodically arranged at the upper surface side of the semiconductor substrate 10.

The semiconductor device 100 may include one or more pads above the semiconductor substrate 10. The semiconductor device 100 in the present example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in the top view. In implementation of the semiconductor device 100, each pad may be connected to an external circuit via wiring such as a wire.

A gate potential is applied to the gate pad 164. The gate pad 164 is electrically connected to a conductive portion of a gate trench portion of the active portion 160. The semiconductor device 100 includes the gate runner that connects the gate pad 164 to the gate trench portion. In FIG. 1, the gate runner is hatched with diagonal lines.

The gate runner in the present example has an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 in the present example encloses the active portion 160 in the top view. A region enclosed by the outer circumferential gate runner 130 in the top view may be set as the active portion 160. In addition, a well region is formed below the gate runner. The well region is a P type region having a higher concentration than that of the base region described below, and is formed from the upper surface of the semiconductor substrate 10 to a position deeper than that of the base region. A region enclosed by the well region in the top view may be set as the active portion 160.

The outer circumferential gate runner 130 is connected to the gate pad 164. The outer circumferential gate runner 130 is arranged above the semiconductor substrate 10. The outer circumferential gate runner 130 may be a metal wiring containing aluminum or the like.

The active-side gate runner 131 is provided in the active portion 160. Providing the active-side gate runner 131 in the active portion 160 can reduce a variation in a wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 in the present example is provided to extend in the X-axis direction so as to cross the active portion 160 substantially at the center of the Y-axis direction from one outer circumferential gate runner 130 to another outer circumferential gate runner 130 which sandwich the active portion 160. When the active portion 160 is divided by the active-side gate runner 131, the transistor portions 70 and the diode portions 80 may be alternately arranged in the X-axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of the present example includes an edge termination structure portion 150 between the active portion 160 and the end side 162 in top view. The edge termination structure portion 150 of the present example is arranged between the outer circumferential gate runner 130 and the end side 162. The edge termination structure portion 150 reduces an electric field strength at an upper surface side of the semiconductor substrate 10. The edge termination structure portion 150 may include at least one of a guard ring, a field plate, or a RESURF which is annularly provided to enclose the active portion 160.

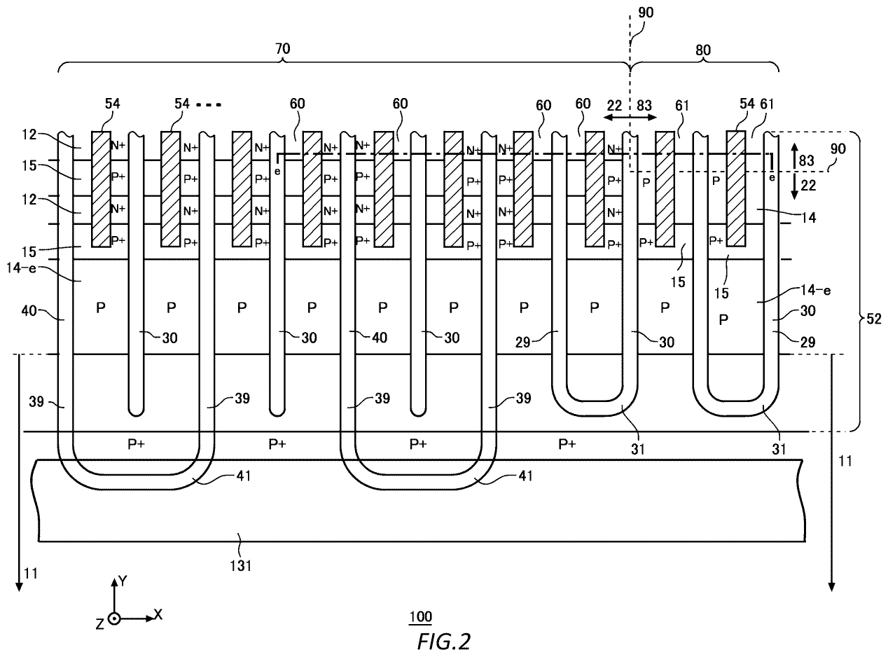

FIG. 2 illustrates an enlarged view of a region D in FIG. 1. The region D is a region including a transistor portion 70, a diode portion 80, and an active-side gate runner 131. The semiconductor device 100 in the present example includes a gate trench portion 40, a dummy trench portion 30, a well region 11, an emitter region 12, a base region 14, and a contact region 15 which are provided inside the upper surface side of the semiconductor substrate 10. Each of the gate trench portion 40 and the dummy trench portion 30 is an example of the trench portion. In addition, the semiconductor device 100 in the present example includes an emitter electrode 52 and the active-side gate runner 131 which are provided above the upper surface of the semiconductor substrate 10. The emitter electrode 52 and the active-side gate runner 131 are provided to be separate from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film in the present example, a contact hole 54 is provided penetrating the interlayer dielectric film. In FIG. 2, each contact hole 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is in contact with the emitter region 12, the contact region 15, and the base region 14 at the upper surface of the semiconductor substrate 10, through the contact hole 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y-axis direction. The dummy conductive portion of the dummy trench portion 30 may not be connected to the emitter electrode 52 and a gate conductive portion, and may be controlled to be at potential different from potential of the emitter electrode 52 and potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y-axis direction. The active-side gate runner 131 is not connected to the dummy conductive portion in the dummy trench portion 30.

The emitter electrode 52 is formed of a material containing metal. FIG. 2 illustrates a range where the emitter electrode 52 is provided. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided to overlap with the active-side gate runner 131. The well region 11 is provided to extend with a predetermined width even in a range that does not overlap with the active-side gate runner 131. The well region 11 in the present example is provided apart from an end of the contact hole 54 in the Y-axis direction toward the active-side gate runner 131 side. The well region 11 is a region of a second conductivity type having a higher doping concentration than that of the base region 14. The base region 14 in the present example is a P-type, and the well region 11 is a P+ type.

Each of the transistor portion 70 and the diode portion 80 has a plurality of trench portions arrayed in the array direction. In the transistor portion 70 in the present example, one or more gate trench portions 40 and one or more dummy trench portions 30 are alternately provided along the array direction. In the diode portion 80 in the present example, the plurality of dummy trench portions 30 are provided along the array direction. In the diode portion 80 in the present example, the gate trench portion 40 is not provided.

The gate trench portion 40 in the present example may have two linear portions 39 extending along the extending direction perpendicular to the array direction (parts of a trench which are linear along the extending direction), and the edge portion 41 connecting the two linear portions 39. The extending direction in FIG. 2 is the Y-axis direction.

At least a part of the edge portion 41 is preferably provided in a curved shape in the top view. By connecting between end portions of the two linear portions 39 in the Y-axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or the plurality of dummy trench portions 30 may be provided. The dummy trench portion 30 may have a linear shape extending in the extending direction, or may have linear portions 29 and an edge portion 31 similar to the gate trench portion 40. The semiconductor device 100 shown in FIG. 2 includes both the linear dummy trench portion 30 having no edge portion 31 and the dummy trench portion 30 having the edge portion 31.

A spread depth of the well region 11 may be deeper than depths of the gate trench portion 40 and the dummy trench portion 30. The end portions in the Y-axis direction of the gate trench portion 40 and the dummy trench portion 30 are provided in the well region 11 in the top view. In other words, at the end portion of each trench portion in the Y-axis direction, a bottom portion of each trench portion in the depth direction is covered with the well region 11. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. A depth position of a lower end of the mesa portion is the same as a depth position of a lower end of the trench portion. The mesa portion in the present example is provided to extend in the extending direction (the Y-axis direction) along the trench, at the upper surface of the semiconductor substrate 10. In the present example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. In the mesa portion, a region arranged to be closest to the active-side gate runner 131, in the base region 14 exposed to the upper surface of the semiconductor substrate 10, is set as a base region 14-e. In FIG. 2, the base region 14-e arranged at one end portion of each mesa portion in the extending direction is illustrated, but the base region 14-e is also arranged at another end portion of each mesa portion. Each mesa portion may be provided with at least one of the emitter region 12 of a first conductivity type, or the contact region 15 of the second conductivity type in a region sandwiched between the base regions 14-e in the top view. In the present example, the emitter region 12 is the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed to the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X-axis direction. As an example, the contact region 15 and the emitter region 12 in the mesa portion 60 are alternately arranged along the extending direction of the trench portion (the Y-axis direction).

In another example, the contact region 15 and the emitter region 12 in the mesa portion 60 may be provided in a stripe shape along the extending direction of the trench portion (the Y-axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base regions 14 and the contact regions 15 may be provided at an upper surface of the mesa portion 61. In the region sandwiched between the base regions 14-e at the upper surface of the mesa portion 61, the contact region 15 may be provided in contact with each of the base regions 14-e. The base region 14 may be provided in a region sandwiched between the contact regions 15 at the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 in the present example is provided above respective regions of the contact region 15, the base region 14, and the emitter region 12. In the diode portion 80, the contact region 15 may not be provided. The contact hole 54 is not provided in regions corresponding to the base region 14-e and the well region 11. The contact hole 54 may be arranged at the center of the mesa portion 60 in the array direction (the X-axis direction).

In the diode portion 80, a cathode region 83 is provided in a region adjacent to the lower surface of the semiconductor substrate 10. The cathode region 83 is a region in which the first cathode region of N+ type and the second cathode region of P type are periodically arranged. In FIG. 2, the first cathode region and the second cathode region are omitted. On the lower surface of the semiconductor substrate 10, a collector region of P type 22 may be provided in a region where the cathode region 83 is not provided. The cathode region 83 and the collector region 22 are provided between a lower surface 23 of the semiconductor substrate 10 and a buffer region 20. The cathode region 83 and the collector region 22 may be in contact with the lower surface 23 of the semiconductor substrate 10. In FIG. 2, a boundary 90 between the cathode region 83 and the collector region 22 is indicated by a dotted line.

The boundary 90 may match the boundary between the transistor portion 70 and the diode portion 80 in a top view from the upper surface 21. The position of the boundary 90 may be on a boundary between the transistor portion 70 and the diode portion 80, which is determined based on the structure of the upper surface 21 side of the semiconductor substrate 10. Among portions in the diode portion 80 which are in contact with the lower surface of the semiconductor substrate 10, the N type regions may be referred to as the first cathode region, and the P type regions may be referred to as the second cathode region. The boundary 90 in the X-axis direction may be positioned in a trench portion that is between the mesa portion 60 positioned closest to the diode portion 80 side of the transistor portion 70 and the mesa portion 61 positioned closest to the transistor portion 70 side of the diode portion 80. The boundary 90 in the X-axis direction may be at the position of the center of the trench portion in the X-axis direction. A trench portion to be the boundary 90 may be a trench portion, among the trench portions in contact with the emitter regions 12, that is closest to the diode portion 80. The trench portion may be a gate trench portion 40 or may be a dummy trench portion 30.

The boundary 90 in the Y-axis direction in a top view from the upper surface 21 may be positioned inward (on the +Y-axis direction side in the present example) relative to the end portion of the contact hole 54 in the Y-axis direction provided in the diode portion 80, and may further be positioned so as to overlap with the base region 14 that is exposed on the upper surface 21. In a top view from upper surface 21, a distance from the end portion of the contact hole 54 in the Y-axis direction provided in the diode portion 80 to the boundary 90 in the Y-axis direction may be equal to or more than a length corresponding to a half of the thickness of the semiconductor substrate 10, may be equal to or more than a length corresponding to 75% of the thickness of the semiconductor substrate 10, or may be equal to or more than a length corresponding to the thickness of the semiconductor substrate 10.

The first cathode region included in the cathode region 83 is arranged apart from the well region 11 in the Y-axis direction. With this configuration, the distance between the P type region (the well region 11) which has a relatively high doping concentration and which is formed to a deep position and the first cathode region of N+ type is secured, so that the breakdown voltage can be improved. The end portion of the first cathode region in the Y-axis direction of the present example is arranged farther away from the well region 11 than the end portion of the contact hole 54 in the Y-axis direction. In another example, the end portion of the first cathode region in the Y-axis direction may be arranged between the well region 11 and the contact hole 54.

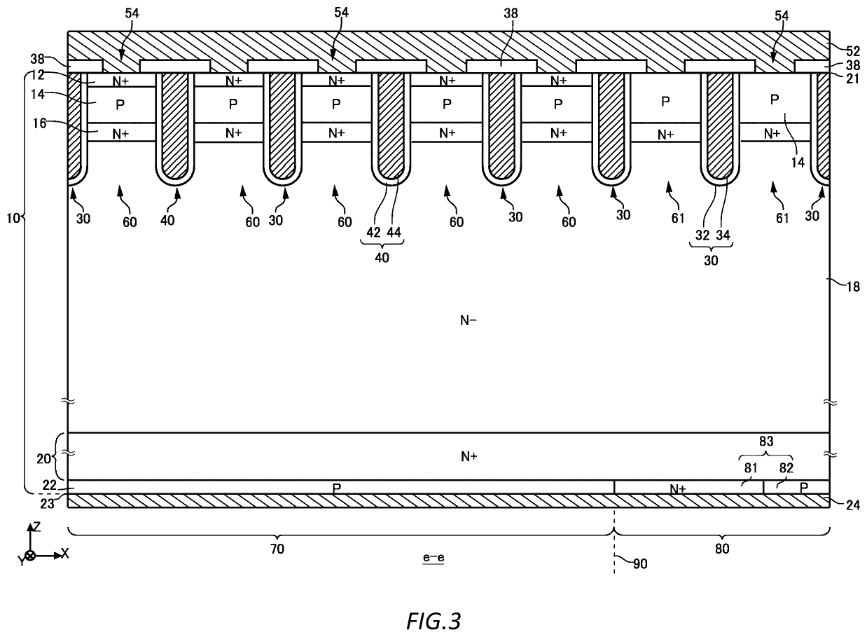

FIG. 3 is a view illustrating an example of a cross-section e-e in FIG. 2. The cross-section e-e is an XZ plane passing through the emitter region 12 and the cathode region 83. The cathode region 83 includes the first cathode region 81 of N+ type and the second cathode region 82 of P type. The semiconductor device 100 in the present example includes the semiconductor substrate 10, an interlayer dielectric film 38, the emitter electrode 52, and a collector electrode 24 in the cross-section.

The interlayer dielectric film 38 is provided on the upper surface of the semiconductor substrate 10. The interlayer dielectric film 38 is a film including at least one layer of a dielectric film such as silicate glass to which an impurity such as boron or phosphorus is added, a thermal oxide film, or other dielectric films. The interlayer dielectric film 38 is provided with a contact hole 54 described with reference to FIG. 2.

The emitter electrode 52 is provided above the interlayer dielectric film 38. The emitter electrode 52 is in contact with the upper surface 21 of the semiconductor substrate 10 through the contact hole 54 of the interlayer dielectric film 38. The collector electrode 24 is provided at the lower surface 23 of the semiconductor substrate 10. The emitter electrode 52 and the collector electrode 24 are formed of a metal material such as aluminum. In the present specification, a direction (the Z-axis direction) in which the emitter electrode 52 is connected to the collector electrode 24 is referred to as the depth direction.

The semiconductor substrate 10 includes a drift region 18 of the N type or the N-type. The drift region 18 is provided in each of the transistor portion 70 and the diode portion 80.

In a mesa portion 60 of the transistor portion 70, the emitter region 12 of an N+ type and a base region 14 of a P-type are provided in order from an upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18.

The emitter region 12 is exposed to the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than that of the drift region 18.

The base region 14 is provided below the emitter region 12. The base region 14 in the present example is provided in contact with the emitter region 12. The base region 14 may be in contact with the trench portions on both sides of the mesa portion 60.

An accumulation region 16 is provided below the base region 14. The accumulation region 16 is a region of the N+ type having a higher doping concentration than that of the drift region 18. That is, the accumulation region 16 has a higher donor concentration than that of the drift region 18. Providing the accumulation region 16 having a high concentration between the drift region 18 and the base region 14 can increase a carrier injection enhancement effect (IE effect) and reduce an ON-voltage. The accumulation region 16 may be provided so as to cover an entire lower surface of the base region 14 in each mesa portion 60.

A mesa portion 61 of the diode portion 80 is provided with the base region 14 of the P-type in contact with the upper surface 21 of the semiconductor substrate 10. The base region 14 of the diode portion 80 functions as an anode region of the diode portion 80. The drift region 18 is provided below the base region 14. In the mesa portion 61, the accumulation region 16 may be provided below the base region 14.

In each of the transistor portion 70 and the diode portion 80, the buffer region 20 of the N+ type may be provided below the drift region 18. A doping concentration of the buffer region 20 is higher than the doping concentration of the drift region 18. The buffer region 20 may have a concentration peak having a higher doping concentration than that of the drift region 18. A doping concentration at a concentration peak refers to a doping concentration at an apex of the concentration peak. In addition, as the doping concentration of the drift region 18, an average value of doping concentrations in a region where doping concentration distribution is substantially flat may be used.

The buffer region 20 may have two or more concentration peaks in the depth direction (the Z-axis direction) of the semiconductor substrate 10. The concentration peak of the buffer region 20 may be provided, for example, at the same depth position as that of a chemical concentration peak of hydrogen (a proton) or phosphorous. The buffer region 20 may function as a field stop layer which prevents a depletion layer widening from a lower end of the base region 14 from reaching the collector region 22 and the cathode region 83.

In the transistor portion 70, the collector region 22 of the P type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

In the diode portion 80, the first cathode region 81 of N type and the second cathode region 82 of P type are provided below the buffer region 20. In the example of FIG. 3, the first cathode region 81 is in contact with the collector region 22, although the second cathode region 82 may be in contact with the collector region 22.

A donor concentration of the first cathode region 81 is higher than a donor concentration of the drift region 18. The donor of the first cathode region 81 is arsenic, hydrogen, or phosphorus, for example. The acceptor of the second cathode region 82 is boron, indium, or aluminum, for example. The acceptor concentration of the second cathode region 82 may be higher than the acceptor concentration of the base region 14. The acceptor concentration of the second cathode region 82 may be the same as or different from the acceptor concentration of the collector region 22. It should be noted that an element serving as a donor and an acceptor in each region is not limited to the example described above.

When the acceptor concentrations of the second cathode region 82 and the collector region 22 are the same, and when the second cathode region 82 and the collector region 22 are in contact with each other, the trench portion between the mesa portion 60 in which the emitter region 12 is arranged and the mesa portion 61 in which no emitter region 12 is arranged may be defined as the boundary position between the second cathode region 82 and the collector region 22. More specifically, the center position of the trench portion in the X-axis direction may be defined as the boundary position between the second cathode region 82 and the collector region 22.

The collector region 22 and the cathode region 83 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided at the upper surface 21 side of the semiconductor substrate 10. Each trench portion passes through the base region 14, and is provided from the upper surface 21 of the semiconductor substrate 10 to a region below the base region 14. In a region where at least any of the emitter region 12, the contact region 15, or the accumulation region 16 is provided, each trench portion also passes through the doping regions of these. A structure in which the trench portion passes through the doping region is not limited to a structure which is made by forming the doping region and then forming the trench portion in order. A structure in which the trench portion is formed and then the doping region is formed between the trench portions is also included in the structure in which the trench portion passes through the doping region.

As described above, the transistor portion 70 is provided with the gate trench portion 40 and the dummy trench portion 30. The diode portion 80 is provided with the dummy trench portion 30, and is not provided with the gate trench portion 40. In the present example, on the boundary 90 between the diode portion 80 and the transistor portion 70 in the X-axis direction, a boundary between the cathode region 83 and the collector region 22 is arranged.

The gate trench portion 40 includes a gate trench provided in the upper surface 21 of the semiconductor substrate 10, a gate dielectric film 42, and a gate conductive portion 44. The gate dielectric film 42 is provided to cover an inner wall of the gate trench. The gate dielectric film 42 may be formed by oxidizing or nitriding a semiconductor on the inner wall of the gate trench. The gate conductive portion 44 is provided farther inward than the gate dielectric film 42 inside the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided to be longer than the base region 14 in the depth direction. The gate trench portion 40 in the cross-section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as that of the gate trench portions 40 in the cross-section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided to cover an inner wall of the dummy trench. The dummy conductive portion 34 is provided inside the dummy trench, and is provided farther inward than the dummy dielectric film 32. The dummy dielectric film 32 insulates the dummy conductive portion 34 from the semiconductor substrate 10. The dummy conductive portion 34 may be formed of the same material as that of the gate conductive portion 44. For example, the dummy conductive portion 34 is formed of a conductive material such as polysilicon. The dummy conductive portion 34 may have the same length as that of the gate conductive portion 44 in the depth direction.

The gate trench portion 40 and the dummy trench portion 30 in the present example are covered with the interlayer dielectric film 38 on the upper surface 21 of the semiconductor substrate 10. It should be noted that bottom portions of the dummy trench portion 30 and the gate trench portion 40 may have curved surfaces which are convex downward (curved shapes in the cross-sections).

By the diode portion 80 including the second cathode region 82, positive holes in the drift region 18 or the like can be extracted via the second cathode region 82. Thus, accumulation of positive holes in the diode portion 80 in the ON-state can be suppressed, and the loss during reverse recovery can be reduced. Also, by the provision of the second cathode region 82, the forward voltage in the diode portion 80 in the ON-state varies. The characteristics of the reverse recovery loss, the forward voltage, and the like can be adjusted by adjusting the arrangement of the first cathode region 81 and the second cathode region 82.

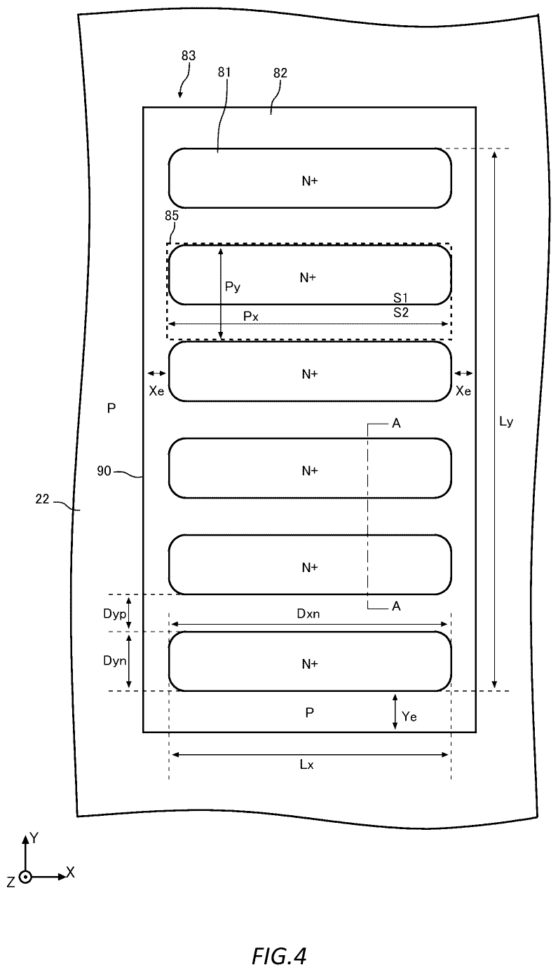

FIG. 4 shows an exemplary arrangement of the first cathode region 81 and the second cathode region 82 on the lower surface 23 of the semiconductor substrate 10. FIG. 4 shows the exemplary arrangement of the first cathode region 81 and the second cathode region 82 in one diode portion 80. The arrangement of the first cathode region 81 and the second cathode region 82 in all the diode portions 80 may be any of those described in the present specification. FIG. 4 also shows the collector region 22 around the diode portion 80.

The first cathode region 81 and the second cathode region 82 of the present example are provided alternately in the first direction. In the second direction that intersects the first direction, one or more first cathode regions 81 are provided. In the example of FIG. 4, only one first cathode region 81 is provided in the second direction. That is, in the second direction, the first cathode regions 81 are not provided discretely. The first direction and the second direction may be orthogonal. The first direction is the Y-axis direction, and the second direction is the X-axis direction in the example of FIG. 4.

The structure in which the first cathode region 81 and the second cathode region 82 are alternately arranged in a predetermined direction is referred to as the repetition structure 85. In the example of FIG. 4, the repetition structure 85 includes only one set of the first cathode region 81 and the second cathode region 82 alternately arranged in the first direction. In the diode portion 80, at least two repetition structures 85 are provided next to each other in the first direction.

A length between both ends of one or more first cathode regions 81 in the X-axis direction provided in one diode portion 80 is denoted by Lx. When only one first cathode region 81 is provided in the X-axis direction, the length Lx is a length of the one first cathode region 81 in the X-axis direction. When a plurality of first cathode regions 81 are provided in the X-axis direction, the length Lx is a length of a region that extends from the first cathode region 81 arranged on one end to the first cathode region 81 arranged on another end in the X-axis direction among the plurality of first cathode regions 81.

A length between both ends of one or more first cathode regions 81 in the Y-axis direction provided in one diode portion 80 is denoted by Ly. As shown in FIG. 4, when a plurality of first cathode regions 81 are provided in the Y-axis direction, the length Ly is a length of a region that extends from the first cathode region 81 arranged on one end to the first cathode region 81 arranged on another end in the Y-axis direction among the plurality of first cathode regions 81.

The diode portion 80 of the present example has a longitudinal length along the first direction (the Y-axis direction in the present example). The diode portion 80 may have the longitudinal length along the first direction if the length Ly is larger than the length Lx. The trench portion provided in the transistor portion 70 or the diode portion 80 may have the longitudinal length in the first direction. The gate trench portion 40 of the transistor portion 70 may have the longitudinal length along the first direction. A direction that is parallel to the longest straight line among the end sides of the trench portion in a top view may be defined as the longitudinal direction of the trench portion.

A width of one first cathode region 81 in the X-axis direction is denoted by Dxn. As shown in FIG. 4, when the first cathode region 81 is surrounded by the second cathode region 82 in a top view, the first cathode region 81 surrounded by the second cathode region 82 is defined as one first cathode region 81. The maximum width of the first cathode region 81 in the X-axis direction may be used as the width Dxn. A width of one first cathode region 81 in the Y-axis direction is denoted by Dyn. The maximum width of the first cathode region 81 in the Y-axis direction may be used as the width Dyn.

A width of one second cathode region 82 in the Y-axis direction is denoted by Dyp. As shown in FIG. 4, when the second cathode region 82 surrounds a plurality of first cathode regions 81 in a top view, a width of a portion of the second cathode region 82 that is sandwiched by two first cathode regions 81 in the Y-axis direction is defined as the width Dyp. The minimum width of the second cathode region 82 in the Y-axis direction sandwiched by two first cathode regions 81 may be used as the width Dyp.

In present specification, a length (Px and Py in the present example) of the repetition structure 85 in a direction (the X-axis direction and the Y-axis direction in FIG. 4) in which the first cathode region 81 and the second cathode region 82 are alternately arranged may be referred to as a repetition pitch of the first cathode region 81 and the second cathode region 82 in each direction. The length Px of the repetition structure 85 of the present example in the X-axis direction is the same as the width Dxn of the first cathode region 81. The length Py of the repetition structure 85 of the present example in the Y-axis direction is the sum of the width Dyn of the first cathode region 81 and the width Dyp of the second cathode region 82. Also, an area of the first cathode region 81 included in one repetition structure 85 is denoted by S1, and an area of the second cathode region 82 included in one repetition structure 85 is denoted by S2. A total sum of areas S1 of the first cathode regions 81 in one diode portion 80 is denoted by a total area Sn, and a total sum of areas S2 of the second cathode regions 82 in one diode portion 80 is denoted by a total area Sp.

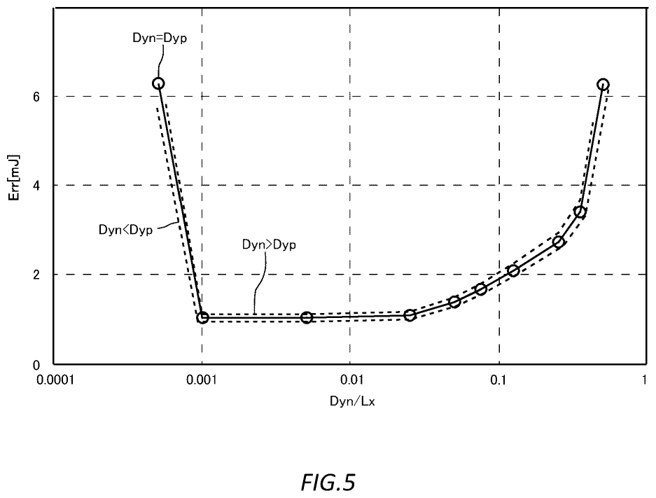

FIG. 5 shows a relationship between the ratio between the length Lx and the width Dyn and a reverse recovery loss Err. In the present example, Dxn=Lx as shown in FIG. 4. In FIG. 5, a case in which the width Dyn and the width Dyp are the same is shown by a solid line. Also, a case in which the width Dyn is larger than the width Dyp and a case in which the width Dyn is smaller than the width Dyp are shown by a dashed line.

In any case, the reverse recovery loss Err increases as the ratio Dyn/Lx approaches 1. On the other hand, the reverse recovery loss Err significantly decreases when the ratio Dyn/Lx becomes 0.1 or less. When the width Dyn of the first cathode region 81 is small, positive holes existing above the first cathode region 81 during reverse recovery can be extracted more easily by the adjoining second cathode region 82. Thus, the reverse recovery loss Err can be reduced. In the diode portion 80, the ratio Dyn/Lx may be 0.1 or less.

When the width Dyn of the first cathode region 81 is too small, it becomes difficult for the diode portion 80 to perform diode operation. In the example of FIG. 5, when the ratio Dyn/Lx becomes smaller than 0.001, an abnormal value is shown where the reverse recovery loss Err sharply increases. In the diode portion 80, the ratio Dyn/Lx may be 0.001 or more.

At least one diode portion 80 may satisfy Expression 1.

$$0.001 < Dyn / Lx \leq 0.1 \qquad ( 1 )$$

All the diode portions 80 may satisfy Expression 1. The upper limit value of the ratio Dyn/Lx, which is indicated by the right-hand side of Expression 1, may be 0.05, 0.03, or 0.01. The lower limit value of the ratio Dyn/Lx, which is indicated by the left-hand side of Expression 1, may be 0.003, 0.005, or 0.01.

The width Dyn may be the same as the width Dyp. The width Dyn may be smaller than the width Dyp. The width Dyn may be 90% or less, 75% or less, or 50% or less of the width Dyp. The width Dyn may be 10% or more, 20% or more, or 30% or more of the width Dyp.

The width Dyn may be larger than the width Dyp. In this case, it becomes easier to secure the region that operates as a diode. The width Dyn may be 110% or more, 125% or more, or 150% or more of the width Dyp. The width Dyn may be 300% or less, 200% or less, or 175% or less of the width Dyp.

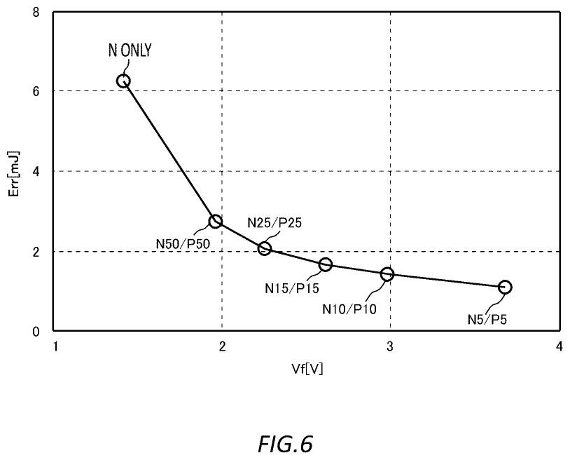

FIG. 6 shows a relationship between a forward voltage Vf and a reverse recovery loss Err of the diode portion 80 when the width Dyn and the width Dyp are varied. In the present example, the width Dyn and the width Dyp are the same. In FIG. 6, N50/P50, N25/P25, N15/P15, N10/P10, and N5/P5 show the examples in which the width Dyn and the width Dyp are each 50 μm, 25 μm, 15 μm, 10 μm and 5 μm. A plotted point labeled as “N ONLY” in FIG. 6 shows the example in which no second cathode region 82 is included. Although the diode portion 80 of FIG. 6 has the structure shown in FIG. 4, the diode portion 80 having any other structures described herein also exhibited similar characteristics.

As shown in FIG. 6, the forward voltage Vf and the reverse recovery loss Err in the diode portion 80 have a trade-off relationship. That is, the lower the reverse recovery loss is, the higher the forward voltage becomes. When the forward voltage becomes high, the loss during the ON-state of the diode portion 80 increases.

In order to adjust the forward voltage Vf and the reverse recovery loss Err, a carrier lifetime killer may be formed in the diode portion 80. For example, by forming charged particles of helium or the like below the anode region of the diode portion 80, a recombination center of the carriers can be formed in this place, and the carrier lifetime can be reduced.

In the semiconductor device 100 of the present example, the carrier lifetime killer may not be formed in the diode portion 80. As shown in FIG. 6, the forward voltage Vf and the reverse recovery loss Err can be adjusted by adjusting the width Dyn and the width Dyp. As shown in FIG. 6, the reverse recovery loss Err decreases and the forward voltage Vf increases as the width Dyn and the width Dyp becomes smaller.

FIG. 6 shows the characteristics when the width Dyn and the width Dyp are the same. Meanwhile, even when the width Dyn is larger than the width Dyp, and also even when the width Dyn is smaller than the width Dyp, the reverse recovery loss Err decreases and the forward voltage Vf increases as the width Dyn and the width Dyp becomes smaller, as is the case with FIG. 6.

The carrier lifetime in the drift region 18 of the diode portion 80 may be 1 μs or more throughout the entire drift region 18. The carrier lifetime may be 2 μs or more, or 3 μs or more. The carrier lifetime may be 10 μs or more, 20 μs or more, or 30 μs or more. The carrier lifetime may be 10 ms or less, 1 ms or less, 500 μs or less, 200 μs or less, or 100 μs or less. Also, no helium may exist in the drift region 18 of the diode portion 80. The carrier lifetime in the drift region 18 of the diode portion 80 may exhibit a maximum value inside the semiconductor substrate 10. This allows the process to form the carrier lifetime killer to be omitted, and the manufacturing process can be simplified. Also, it is possible to prevent the occurrence of leakage current due to carrier recombination centers or generation centers.

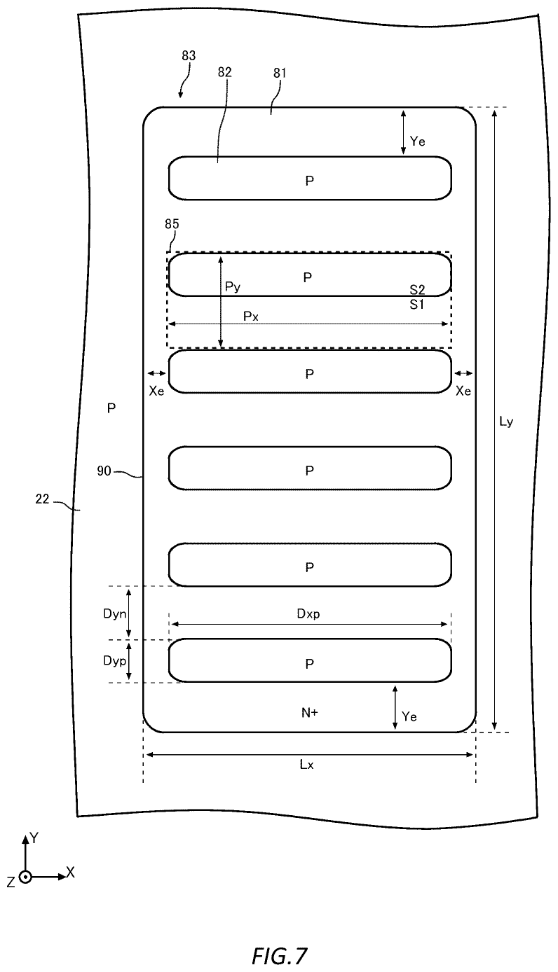

FIG. 7 shows another exemplary arrangement of the first cathode region 81 and the second cathode region 82. In the present example, the first cathode region 81 shown in FIG. 4 is replaced by the second cathode region 82, and the second cathode region 82 is replaced by the first cathode region 81. Other structures are similar to those of the example in FIG. 4. Also, in the structures shown in the respective drawings of the present specification, the first cathode region 81 may be replaced by the second cathode region 82, and the second cathode region 82 may be replaced by the first cathode region 81.

In the present example, a width of the first cathode region 81 in the Y-axis direction sandwiched by two second cathode regions 82 in the Y-axis direction is denoted by Dyn. Also, the maximum width of the first cathode region 81 in the X-axis direction is denoted by Lx, and its maximum width in the Y-axis direction is denoted by Ly. Also in the present example, the diode portion 80 exhibited similar characteristics to those of FIG. 5 and FIG. 6. Also in the present example, the widths Dyn, Dyp and the length Lx may have a similar relationship to those of the example described in FIG. 5.

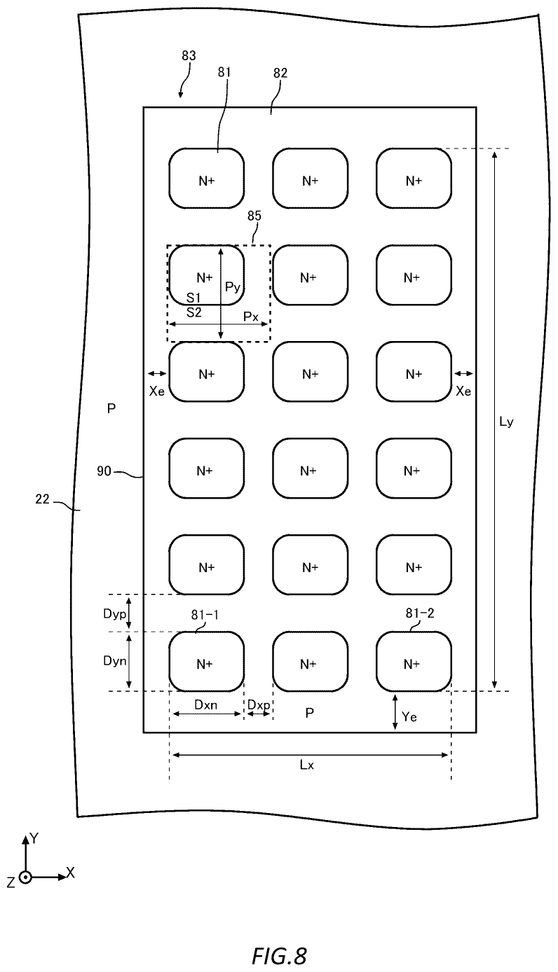

FIG. 8 shows another exemplary arrangement of the first cathode region 81 and the second cathode region 82 on the lower surface 23 of the semiconductor substrate 10. The first cathode region 81 and the second cathode region 82 of the present example are provided alternately in both the first direction and the second direction. The first direction and the second direction in the present example are orthogonal to each other. The first direction is the Y-axis direction, and the second direction is the X-axis direction in the example of FIG. 8. In the present example, a plurality of repetition structures 85 are arranged next to each other in both the first direction and the second direction.

In the present example, a plurality of first cathode regions 81 are discretely arranged also in the X-axis direction. A width of a portion of the second cathode region 82 sandwiched by two first cathode regions 81 in the X-axis direction is denoted by the width Dxp. The minimum width of the second cathode region 82 in the X-axis direction sandwiched by two first cathode regions 81 may be used as the width Dxp.

When a plurality of first cathode regions 81 are provided in the X-axis direction, the length Lx is a length between both ends of the plurality of first cathode regions 81 in the X-axis direction. Among the plurality of first cathode regions 81, one that is arranged at the end of the negative side in the X-axis direction is denoted by the first cathode region 81-1, and one that is arranged at the end of the positive side in the X-axis direction is denoted by the first cathode region 81-2. The length Lx is a length extending from the end portion of the first cathode region 81-1 on the negative side in the X-axis direction to the end portion of the first cathode region 81-2 on the positive side in the X-axis direction. The definitions of length, width, and area other than the width Dxp and the length Lx are similar to those of the example in FIG. 4.

Also in the present example, the width Dxp and the length Lx may have a similar relationship to those of the example described in FIG. 5. This enables the reduction of the reverse recovery loss Err. Also, at least one diode portion 80 may satisfy Expression 2.

$$0.001 < Dxn / Ly \leq 0.1 \qquad ( 2 )$$

All the diode portions 80 may satisfy Expression 2.

The upper limit value of the ratio Dxn/Ly, which is indicated by the right-hand side of Expression 2, may be 0.05, 0.03, or 0.01. The lower limit value of the ratio Dxn/Ly, which is indicated by the left-hand side of Expression 2, may be 0.003, 0.005, or 0.01.

By alternately arranging the first cathode region 81 and the second cathode region 82 both in the first direction and the second direction, positive holes above the first cathode region 81 can be extracted more easily from the second cathode region 82. Thus, the reverse recovery loss Err can be further reduced.

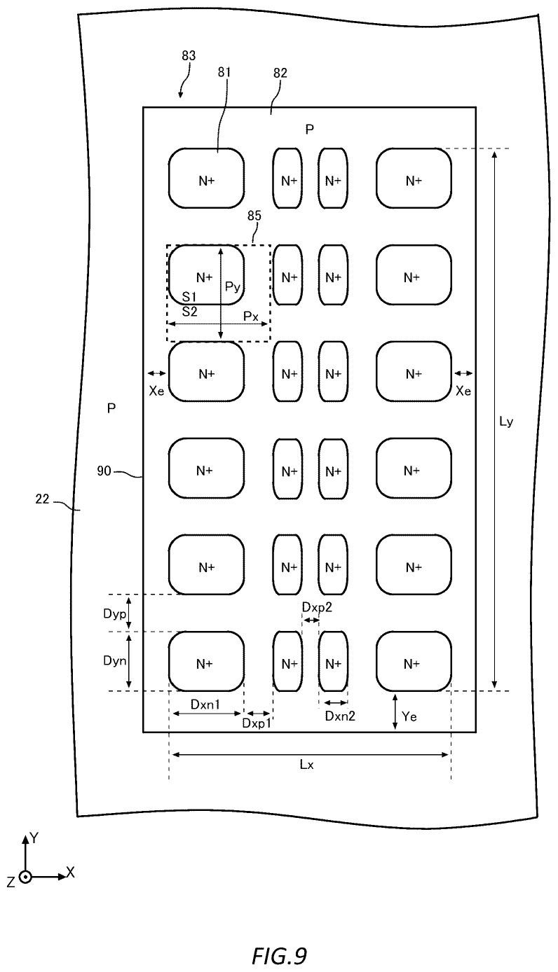

FIG. 9 shows another exemplary arrangement of the first cathode region 81 and the second cathode region 82 on the lower surface 23 of the semiconductor substrate 10. The diode portion 80 of the present example is different from the example of FIG. 8 in its arrangement of the first cathode region 81 and the second cathode region 82 in the X-axis direction. Other structures are similar to those of the example in FIG. 8. Also in the present example, the widths Dyn, Dyp and the length Lx may have a similar relationship to those of the example described in FIG. 5. This enables the reduction of the reverse recovery loss Err.

Among a plurality of first cathode regions 81 provided next to each other in the X-axis direction, a width of one first cathode region 81 in the X-axis direction that is closest to the center of the diode portion 80 in the X-axis direction is denoted by Dxn2. Among a plurality of first cathode regions 81 provided next to each other in the X-axis direction, a width of one first cathode region 81 in the X-axis direction that is closest to the end portion of the diode portion 80 in the X-axis direction is denoted by Dxn1. In the present example, the width Dxn2 is smaller than the width Dxn1.

Among the second cathode regions 82 sandwiched by two first cathode regions 81 in the X-axis direction, a width of one in the X-axis direction closest to the center of the diode portion 80 in the X-axis direction is denoted by Dxp2. The width Dxp2 corresponds to a space between the first cathode regions 81 in the center of the diode portion 80 in the X-axis direction.

Among the second cathode regions 82 sandwiched by two first cathode regions 81 in the X-axis direction, a width of one in the X-axis direction closest to the end portion of the diode portion 80 in the X-axis direction is denoted by Dxp1. The width Dxp1 corresponds to a space between the first cathode regions 81 in the end portion of the diode portion 80 in the X-axis direction. In the present example, the width Dxp2 is smaller than the width Dxp1.

When the semiconductor device 100, such as an RC-IGBT, is operated, the temperature near the center of the diode portion 80 may become higher than that in other regions. In contrast, as in the present example, by reducing the width of at least one of the first cathode region 81 or the second cathode region 82 in the center of the diode portion 80, an increase in temperature in the center of the diode portion 80 can be suppressed. The width Dxp2 may be ¾ times or less, or half or less of the width Dxp1. The width Dxn2 may be ¾ times or less, or half or less of the width Dxn1. A density of the second cathode region 82 in the center of the diode portion 80 may be higher than the density of the second cathode region 82 in the end portion of the diode portion 80. The density of the second cathode region 82 refers to a ratio of an area of the second cathode region 82 relative to a unit area.

In the example of FIG. 9, the width Dyn of the first cathode region 81 in the Y-axis direction is constant, and the width Dyp of the second cathode region 82 is also constant. In other examples, the width Dyn in the center of the diode portion 80 in the Y-axis direction may be smaller than the width Dyn in the end portion of the diode portion 80 in the Y-axis direction. Similarly, the width Dyp in the center of the diode portion 80 in the Y-axis direction may be smaller than the width Dyp in the end portion of the diode portion 80 in the Y-axis direction. This allows the temperature increase in the center of the diode portion 80 to be suppressed, also in the Y-axis direction.

In one first cathode region 81 arranged in the end portion of the diode portion 80 in the X-axis direction, the width Dxn1 in the X-axis direction may be larger than the width Dyn in the Y-axis direction. The width Dxn1 and the width Dyn may satisfy the following Expression 3.

$$0.001 < Dyn / Dxn < 1 \qquad ( 3 )$$

The upper limit value of the ratio Dyn/Dxn1, which is indicated by the right-hand side of Expression 3, may be 0.9 or 0.8. The lower limit value of the ratio Dyn/Dxn1, which is indicated by the left-hand side of Expression 3, may be 0.01 or 0.1.

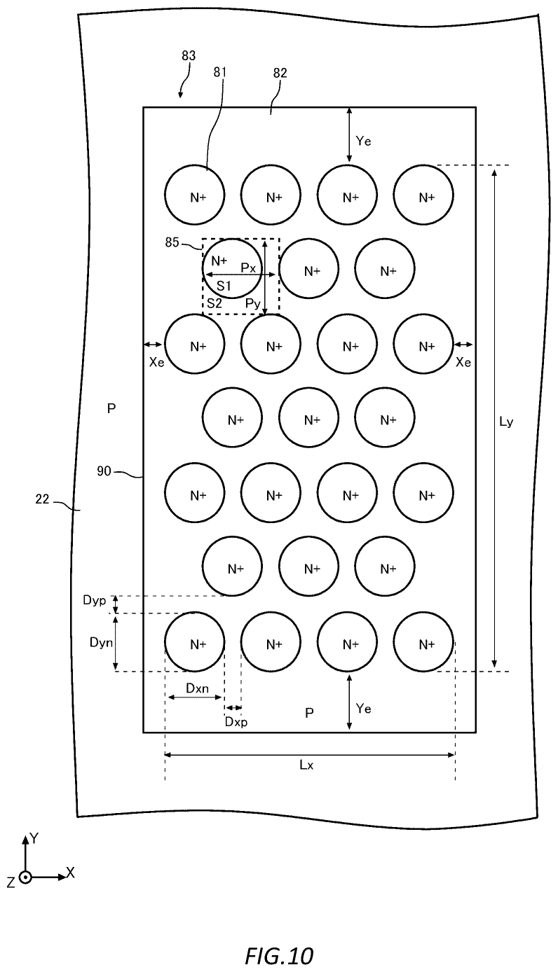

FIG. 10 shows another exemplary arrangement of the first cathode region 81 and the second cathode region 82 on the lower surface 23 of the semiconductor substrate 10. The first cathode regions 81 of the present example are discretely arranged in both the X-axis direction and the Y-axis direction, as is the case with the example of FIG. 8. However, in the present example, two first cathode regions 81 that are next to each other in the Y-axis direction are arranged at different positions on the X-axis from each other. The first cathode regions 81 of the present example are arranged at equal intervals along the X-axis direction, and also arranged at equal intervals along a direction extending at an angle smaller than 90 degrees relative to the X-axis direction.

In each of the examples of FIGS. 8 to 10, the shape of the first cathode region 81 in a top view may be substantially rectangular as shown in FIG. 8, or may be circular as shown in FIG. 10, or may be any other shape. Also in the present example, the width Dxp and the length Lx may have a similar relationship to those of the example described in FIG. 5. This enables the reduction of the reverse recovery loss Err.

In each example described herein, the total area Sn of the first cathode regions 81 and the total area Sp of the second cathode regions 82 may satisfy the following Expression 4.

$$0.1 \leq Sn / ( Sn + Sp ) < 1 \qquad ( 4 )$$

As described above, by providing the second cathode regions 82 in the diode portion 80, the reverse recovery loss Err can be reduced.

The total area Sn of the first cathode regions 81 and the total area Sp of the second cathode regions 82 may satisfy the following Expression 5.

$$0.4 \leq Sn / ( Sn + Sp ) < 0.8 \qquad ( 5 )$$

By setting the total area Sp of the second cathode regions 82 to 20% or more of the entire area, the reverse recovery loss Err can be reduced more easily. Also, by setting the total area Sn of the first cathode regions 81 to 40% or more of the entire area, the functionality as the diode portion 80 can be maintained more easily.

The total area Sn of the first cathode regions 81 and the total area Sp of the second cathode regions 82 may satisfy the following Expression 6.

$$0.5 \leq Sn / ( Sn + Sp ) < 0.75 \qquad ( 6 )$$

By setting the total area Sp of the second cathode regions 82 to 25% or more of the entire area, the reverse recovery loss Err can be reduced even more easily. Also, by setting the total area Sn of the first cathode regions 81 to 50% or more of the entire area, the functionality as the diode portion 80 can be maintained even more easily. The proportion of the area Sn/(Sn+Sp) may be 0.7 or less, or 0.65 or less.

In Expressions 4 to 6, the total area Sn may be replaced by the area S1, and the total area Sp may be replaced by the area S2. Even in such a case, a similar effect to Expressions 4 to 6 can be obtained.

In each example described herein, the width Dyp of one second cathode region 82 and the width Dyn of one first cathode region 81 may satisfy the following Expression 7-1.

$$0.1 \leq Dyn / ( Dyn + Dyp ) < 1 \qquad ( 7 - 1 )$$

As described above, by providing the second cathode regions 82 in the diode portion 80, the reverse recovery loss Err can be reduced.

The width Dyp of one second cathode region 82 and the width Dyn of one first cathode region 81 may satisfy the following Expression 8-1.

$$0.4 \leq Dyn / ( Dyn + Dyp ) < 0.8 \qquad ( 8 - 1 )$$

By setting the width of the second cathode regions 82 to 20% or more of the entire width, the reverse recovery loss Err can be reduced more easily. Also, by setting the width of the first cathode regions 81 to 40% or more of the entire width, the functionality as the diode portion 80 can be maintained more easily.

The width Dyp of one second cathode region 82 and the width Dyn of one first cathode region 81 may satisfy the following Expression 9-1.

$$0.5 \leq Dyn / ( Dyn + Dyp ) < 0.75 \qquad ( 9 - 1 )$$

By setting the width of the second cathode regions 82 to 25% or more of the entire width, the reverse recovery loss Err can be reduced even more easily. Also, by setting the width of the first cathode regions 81 to 50% or more of the entire width, the functionality as the diode portion 80 can be maintained even more easily. The proportion of width Dyn/(Dyn+Dyp) may be 0.7 or less, or 0.65 or less.

The length Lx and the width Dyn shown in FIG. 4 and the like may satisfy the following Expression 10.

$$0.001 < Dyn / Lx \leq 0.4 \qquad ( 10 )$$

As shown in FIG. 5, by setting Dyn/Lx to 0.4 or less, the reverse recovery loss Err can be reduced. In this case, the total area Sn of the first cathode regions 81 and the total area Sp of the second cathode regions 82 may satisfy Expression 6 described above. Also, the width Dyp of one second cathode region 82 and the width Dyn of one first cathode region 81 may satisfy Expression 9-1 described above.

When the first cathode region 81 and the second cathode region 82 are provided alternately also in the X-axis direction, the width Dxp of one second cathode region 82 and the width Dxn of one first cathode region 81 may satisfy any of the following Expressions 7-2, 8-2, or 9-2.

$$0.1 \leq Dxn / ( Dxn + Dxp ) < 1 \qquad ( 7 - 2 )$$

$$0.4 \leq Dxn / ( Dxn + Dxp ) < 0.8 \qquad ( 8 - 2 )$$

$$0.5 \leq Dxn / ( Dxn + Dxp ) < 0.75 \qquad ( 9 - 2 )$$

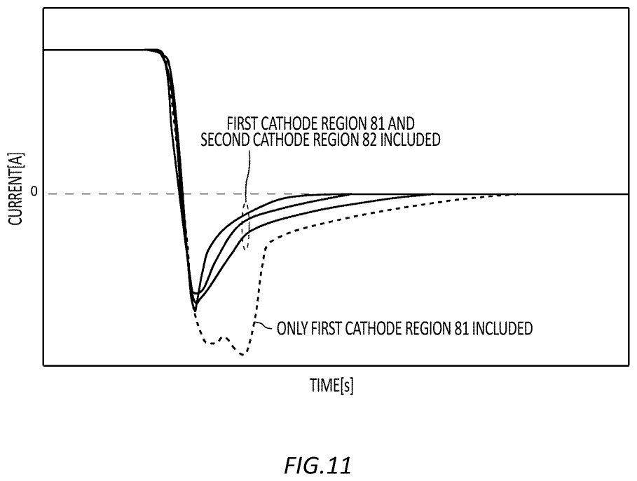

FIG. 11 shows a time waveform of an anodic current during reverse recovery. A waveform depicted in a dashed line in FIG. 11 shows a comparative example in which the first cathode region 81 is included, but no second cathode region 82 is included. Waveforms depicted in a solid line in FIG. 11 show examples in which both the first cathode region 81 and the second cathode region 82 are included. Each of the waveforms of the examples represents an example in which the proportion of the area of the first cathode region 81 and the second cathode region 82 has been varied. In any examples, the reverse recovery current is smaller compared to the comparative example, and the reverse recovery loss Err have been reduced successfully.

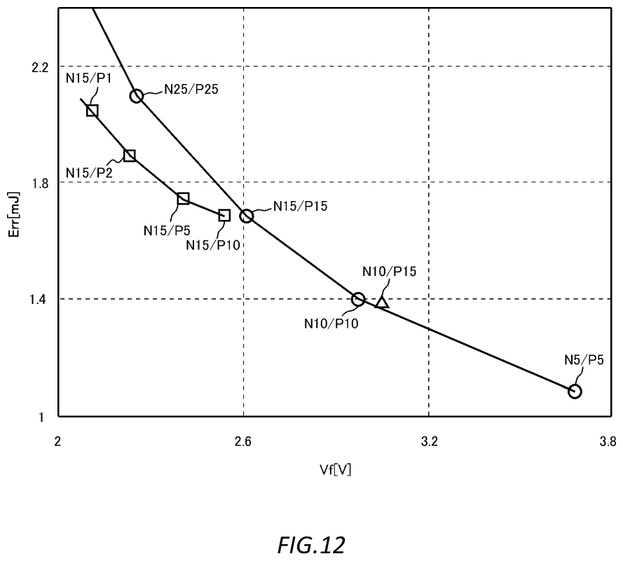

FIG. 12 shows a relationship between a forward voltage Vf and a reverse recovery loss Err of the diode portion 80 when the width Dyn and the width Dyp are varied. The plotted points of N25/P25, N15/P15, N10/P10, and N5/P5 in FIG. 12 are similar to those of the example in FIG. 6. In FIG. 12, the plotted point N15/P1 represents an example of Dyn=15 μm and Dyp=1 μm, the plotted point N15/P2 represents an example of Dyn=15 μm and Dyp=2 μm, the plotted point N15/P5 represents an example of Dyn=15 μm and Dyp=5 μm, the plotted point N15/P10 represents an example of Dyn=15 μm and Dyp=10 μm, and the plotted point N10/P15 represents an example of Dyn=10 μm and Dyp=15 μm. Although the diode portion 80 of FIG. 12 has the structure shown in FIG. 4, the diode portion 80 having any other structures described herein also exhibited similar characteristics.

As shown in the examples of N15/P1, N15/P2, N15/P5, and N15/P10, the trade-off characteristic between the forward voltage Vf and the reverse recovery loss Err shifts downwardly when the width Dyn is larger than the width Dyp. On the other hand, as shown in the example of N10/P15, the trade-off characteristic does not shift significantly when the width Dyp is larger than the width Dyn.

The width Dyn of one first cathode region 81 may be larger than the width Dyp of one second cathode region 82. This can improve the trade-off characteristic between the forward voltage Vf and the reverse recovery loss Err. The width Dyn may be 1.5 times or more, three times or more, five times or more, or ten times or more the width Dyp. The width Dyn may be 50 times or less, or 20 times or less the width Dyp.

The width Dyn may be 5 μm or more, 10 μm or more, 15 μm or more, or 25 μm or more. The width Dyn may be 100 μm or less, or 50 μm or less. The width Dyp may be 15 μm or less, 10 μm or less, 5 μm or less, or 2 μm or less. The width Dyp may be 0.1 μm or more, or 1 μm or more.

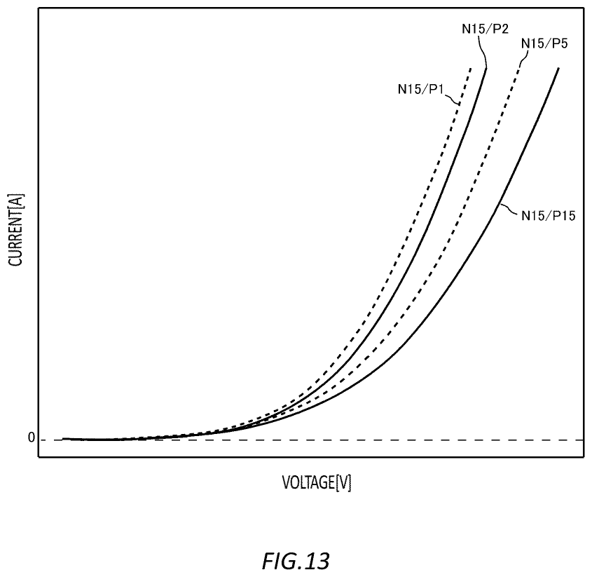

FIG. 13 shows a relationship between the forward voltage of the diode portion 80 and an anode-cathode current when the width Dyp is varied. As shown in FIG. 13, the forward voltage Vf of the diode portion 80 decreases as the width Dyp becomes smaller. Note that the reverse recovery current shown in FIG. 11 tended to increase when the width Dyp was reduced. As shown in FIG. 12, reducing the width Dyp can improve the trade-off characteristic between the forward voltage Vf and the reverse recovery loss Err.

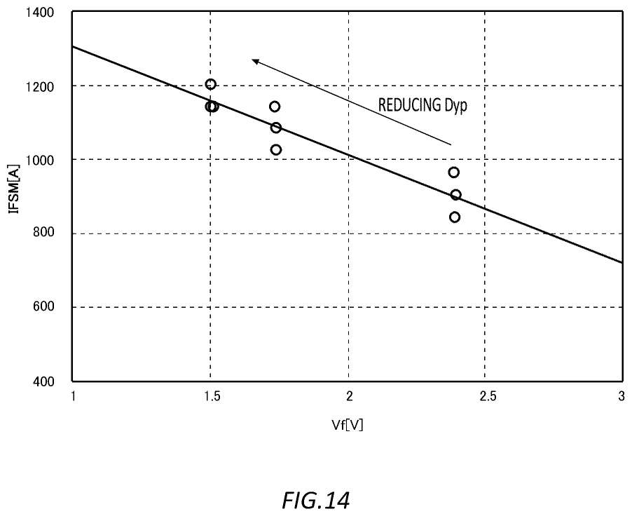

FIG. 14 shows a relationship between the forward voltage Vf and a forward surge current withstand capability (IFSM withstand capability) of the diode portion 80 when the width Dyp is varied. As shown in FIG. 14, reducing the width Dyp causes a reduction of the forward voltage Vf and improves the IFSM withstand capability.

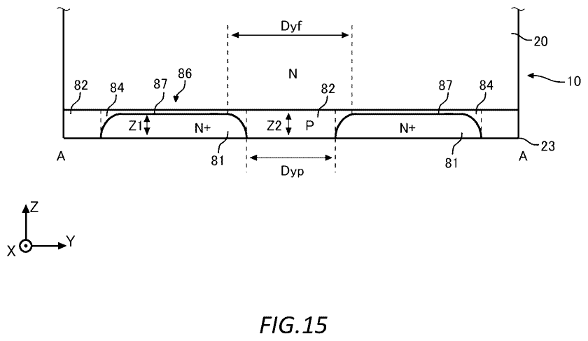

FIG. 15 shows an example of a cross-section A-A shown in FIG. 4. The cross-section A-A is a plane Y-Z that passes through the first cathode region 81 and the second cathode region 82. FIG. 15 shows a vicinity of the lower surface 23 of the semiconductor substrate 10, with the structure on the upper surface 21 side being omitted. Also, although the buffer region 20 is provided on the semiconductor substrate 10 of FIG. 15, the drift region 18 may be provided instead of the buffer region 20.

On the lower surface 23 of the semiconductor substrate 10, the first cathode region 81 and the second cathode region 82 are alternately provided along the Y-axis direction. A width of the first cathode region 81 in a depth direction (Z-axis direction) is denoted by Z1, and a width of the second cathode region 82 in the depth direction is denoted by Z2. The maximum width of the first cathode region 81 in the depth direction may be used as the width Z1. The maximum width of the second cathode region 82 in the depth direction may be used as the width Z2.

The second cathode region 82 is formed by injecting dopant ions of P type into the lower surface 23 of the semiconductor substrate 10 and performing heat treatment. The second cathode region 82 and the collector region 22 of the transistor portion 70 may be formed simultaneously by injecting dopant ions of P type into the entire lower surface 23. The second cathode region 82 may have the same doping concentration as that of the collector region 22.

After the P type region is formed over the entire lower surface 23, the first cathode region 81 can be formed by locally injecting dopant ions of N type and performing heat treatment. The width Z1 of the first cathode region 81 in the depth direction may be smaller than the width Z2 of the second cathode region 82 in the depth direction.

By performing heat treatment after locally injecting dopant ions of N type, the P type dopant spreads also in the Y-axis direction. Thus, if the width Dyp of the second cathode region 82 is designed to be too large, the first cathode region 81 is eliminated due to the spreading of the P type dopant. The first cathode region 81 preferably has a size that allows the first cathode region 81 to be left even when the spreading of the P type dopant in the Y-axis direction is increased due to manufacturing variation or the like.

The width Dyp of one second cathode region 82 in the Y-axis direction may be larger than the width Z2 of the second cathode region 82 in the Z-axis direction. By setting the width Dyp to be large, the first cathode region 81 can be left more easily. The width Dyp may be 1.5 times or more, twice or more, three times or more, or five times or more the width Z2.

The width Dyp of one second cathode region 82 in the Y-axis direction may be larger than the width Z1 of the first cathode region 81 in the Z-axis direction. The larger the width Z1 is, the more easily the first cathode region 81 spreads in the Y-axis direction. Thus, by setting the width Dyp according to the width Z1, the first cathode region 81 can be left more easily. The width Dyp may be 1.5 times or more, twice or more, three times or more, or five times or more the width Z1.

The first cathode region 81 has an upper surface 86 in the depth direction. In the surfaces of the first cathode region 81, a region in which its normal line intersects the upper surface 21 of the semiconductor substrate 10 may be defined as the upper surface 86. The upper surface 86 of the present example includes a flat portion 87 that has a uniform distance to the lower surface 23 of the semiconductor substrate 10. The flat portion 87 includes a portion in which a distance to the lower surface 23 is the maximum width Z1 of the first cathode region 81. The flat portion 87 may refer to a continuous region in which the distance to the lower surface 23 is 90% or more of the maximum width Z1 of the first cathode region 81.

A distance in the Y-axis direction between the flat portions 87 of two first cathode regions 81 that are next to each other in the Y-axis direction is denoted by Dyf. The distance Dyf may be larger than 1.6 times the distance Z1 between the flat portion 87 and the lower surface 23. A portion outside the flat portion 87 in the first cathode region 81 corresponds to a region in which N type dopant is spread due to heat treatment. The N type dopant, such as phosphorus, spreads in the Y-axis direction by approximately 0.8 times the width Z1 of the first cathode region 81. Thus, by setting the distance Dyf to be larger than 1.6 times the width Z1, it becomes easier to cause the second cathode region 82 to be left. The distance Dyf may be larger than 1.6 times the width Z1 by 1 μm or more, by 2 μm or more, by 5 μm or more, by 10 μm or more, or by 15 μm or more. The distance Dyf may be a value or less which is obtained by adding 50 μm, 30 μm, or 15 μm to 1.6 times the width Z1 by.

The semiconductor device 100 may include a third cathode region 84. The third cathode region 84 is a P type region that is in contact with the first cathode region 81 in the depth direction (Z-axis direction) directing from the lower surface 23 of the semiconductor substrate 10 to the upper surface 21, and that is also in contact with the second cathode region 82 in a direction (the X-axis direction or the Y-axis direction) that is parallel to the lower surface 23. The third cathode region 84 of the present example is a P type region between the first cathode region 81 and the buffer region 20 in the Z-axis direction.

The doping concentration of the third cathode region 84 may be lower than the doping concentration of the second cathode region 82. The doping concentration of the third cathode region 84 may be lower than the doping concentration of the first cathode region 81. The second cathode region 82 and the third cathode region 84 may be formed simultaneously in the same ion injection process and in the same annealing process. The PN junction surface between the second cathode region 82 and the buffer region 20 and the PN junction surface between the third cathode region 84 and the buffer region 20 may both be provided at the same depth position from the lower surface 23. That is, the maximum depth from the lower surface 23 of the third cathode region 84 in contact with the first cathode region 81 may be the same as the maximum depth from the lower surface 23 of the second cathode region. Here, being the same maximum depth may include a difference in a range of +10% or less in the maximum depth from the lower surface 23.

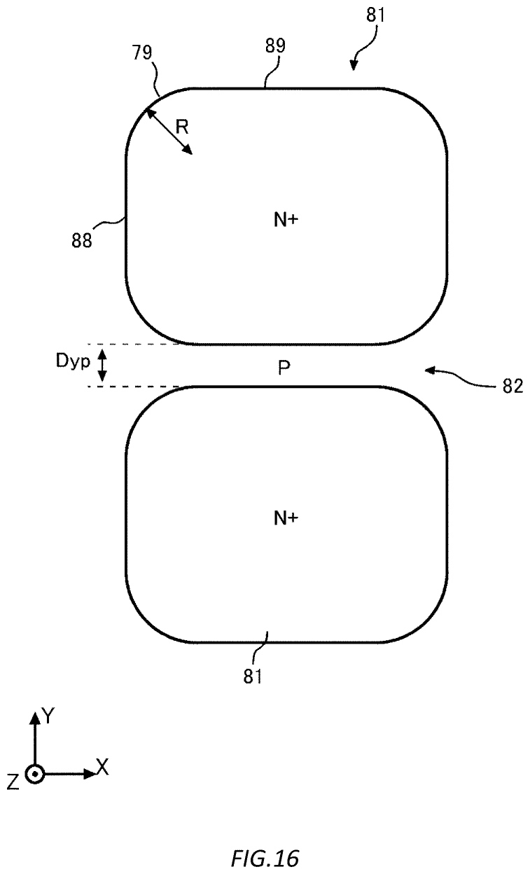

FIG. 16 shows an example of a shape of the first cathode region 81 in a top view. FIG. 16 shows the shape of the first cathode region 81 on the lower surface 23 of the semiconductor substrate 10. The shapes of the first cathode region 81 and the second cathode region 82 in a top view shown in each drawing herein are those on the lower surface 23 of the semiconductor substrate 10.

The first cathode region 81 of the present example includes a first end side 88 that is straight and a second end side 89 that is straight. The second end side 89 has a gradient relative to the first end side 88. The first end side 88 of the present example is parallel to the Y-axis, and the second end side 89 is parallel to the X-axis. In the present example, the first end side 88 and the second end side 89 are connected by a curved line 79. Respective straight end sides of the first cathode region 81 may be connected by a curved line 79. In the example of FIG. 16, the first cathode region 81 has a shape in which the four corners of a rectangle are rounded. By the shape of the first cathode region 81 having the curved line 79, it is possible to reduce the electric field strength at the corner portions of the first cathode region 81.

A radius of curvature of the curved line 79 is denoted by R. When the first cathode region 81 has a plurality of curved lines 79, an average radius of curvature of the plurality of curved lines 79 may be denoted by R. The width Dyp of the second cathode region 82 in the Y-axis direction may be smaller than the radius of curvature R of the curved line 79. By setting the width Dyp of the second cathode region 82 to be small, the reverse recovery loss Err and the forward voltage Vf can be adjusted. The radius of curvature R may be 5 μm or less, 4 μm or less, or 3 μm or less. The radius of curvature R may be 1 μm or more, or 2 μm or more.

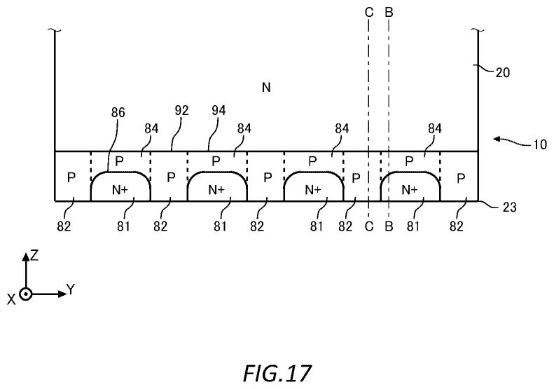

FIG. 17 shows another example of the cross-section Y-Z. The cross-section Y-Z of the present example is a cross-section that covers a larger range in the Y-axis direction than that of the cross-section A-A. The cross-section Y-Z of the present example includes the first cathode regions 81 and the second cathode regions 82 more than those of the cross-section A-A shown in FIG. 15.

As is the case with the example of FIG. 15, the third cathode region 84 is provided between the respective first cathode region 81 and the buffer region 20. The third cathode region 84 may be provided in contact with the upper surface 86 of the first cathode region 81. The third cathode region 84 may cover the entire upper surface 86 of the first cathode region 81.

The upper surface 92 of the second cathode region 82 may be provided in contact with the buffer region 20. The PN junction surface between the second cathode region 82 and the buffer region 20 may be the upper surface 92. The upper surface 94 of the third cathode region 84 may be provided in contact with the buffer region 20. The PN junction surface between the third cathode region 84 and the buffer region 20 may be the upper surface 94. The upper surface 92 and the upper surface 94 may both be provided at the same depth position from the lower surface 23. In the present example, all upper surfaces 92 and all upper surfaces 94 are provided at the same depth position from the lower surface 23. In an upper surface 92, a depth position of a portion that is farthest away from the lower surface 23 may be defined as the depth position of the upper surface 92. Similarly, in an upper surface 94, a depth position of a portion that is farthest away from the lower surface 23 may be defined as the depth position of the upper surface 94.

The third cathode region 84 may be connected to the second cathode region 82. The first cathode region 81 may be sandwiched by two second cathode regions 82 in a direction parallel to the lower surface 23 of the semiconductor substrate 10. The third cathode region 84 may be connected to the two second cathode regions 82 that sandwich the first cathode region 81.

In the present example, the second cathode region 82 and the third cathode region 84 are alternately arranged in the Y-axis direction. In this case, the third cathode region 84 is connected to one or more second cathode regions 82 adjoining in the Y-axis direction. At the same depth position, the second cathode region 82 and the third cathode region 84 may have the same acceptor concentration, or may have a different acceptor concentration. The second cathode region 82 and the third cathode region 84 may be formed simultaneously in the same ion injection process and in the same annealing process.

According to the present example, the second cathode region 82 is provided to extend deeper than the first cathode region 81. Also, the third cathode region 84 is provided on the first cathode region 81. Thus, when the diode portion 80 is turned off, the positive holes can be more easily extracted via the second cathode region 82 and the third cathode region 84, and the reverse recovery time can be shortened. Thus, the reverse recovery loss Err can be reduced. Also, during switching operation of the semiconductor device 100, carriers may be depleted due to the extension of the depletion layer from the upper surface 21 side, leading to oscillation of the voltage or current waveform. By providing the third cathode region 84 on the first cathode region 81, depletion of the carrier can be suppressed, and oscillation of the waveform can be suppressed.

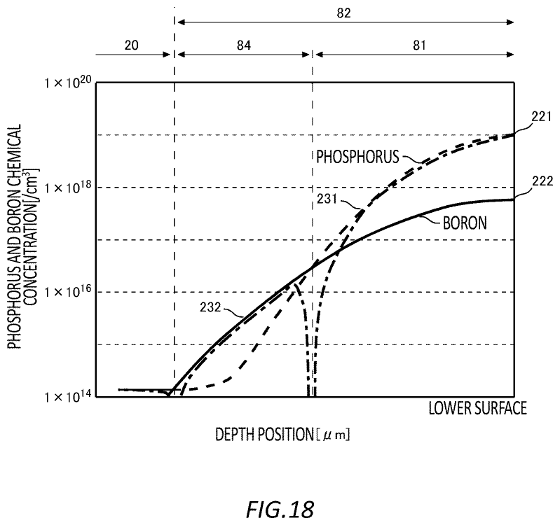

FIG. 18 shows an example of chemical concentration distribution of phosphorus and boron in the first cathode region 81, the second cathode region 82, and the third cathode region 84. In the present example, by injecting boron into the entire region in which the cathode region 83 should be formed, the second cathode region 82 and the third cathode region 84 are formed in the same process. Also, by selectively injecting phosphorus, the first cathode region 81 is formed. Note that the dash-dotted line in FIG. 18 is the doping concentration distribution on the cross-section B-B in FIG. 17.

Since the activation rate of phosphorus and boron is very high, the chemical concentration distribution of phosphorus is approximately identical to the concentration distribution of donor, while the chemical concentration distribution of boron is approximately identical to the concentration distribution of acceptor. Note that the buffer region 20 of the present example is formed by injecting hydrogen. Thus, the phosphorous chemical concentration in the buffer region 20 exhibits a flat distribution. The phosphorous chemical concentration in the buffer region 20 of the present example corresponds to the bulk donor concentration.

In the present example, phosphorus and boron are spread in the depth direction by performing heat treatment on the semiconductor substrate 10 after phosphorus and boron are injected in the vicinity of the lower surface 23 of the semiconductor substrate 10. In the present example, the depth position to which phosphorus and boron are injected is the same. Boron spreads more easily inside the semiconductor substrate 10 than phosphorus. Thus, boron spreads to a position deeper than phosphorus.

The doping concentration in the second cathode region 82 is approximately identical to the chemical concentration of boron. The doping concentration in the first cathode region 81 and the third cathode region 84 corresponds to a difference between phosphorus and boron chemical concentrations. A region where the phosphorous chemical concentration is higher than the boron chemical concentration is the first cathode region 81, whereas a region where the boron chemical concentration is higher than the phosphorous chemical concentration is the third cathode region 84.

The first cathode region 81 may have the first concentration peak 221 of a dopant (phosphorus in the present example) in the depth direction. The concentration peak is a portion of the concentration distribution which represents a mountain shape. The concentration peak may have an apex and a tail portion. The apex is a portion at which the concentration exhibits a maximum value. The tail portion is a portion in which the concentration monotonically decreases with increasing distance from the apex. When the dopant concentration in the first cathode region 81 reaches the maximum value at the position of the lower surface 23 of the semiconductor substrate 10, the lower surface 23 may be defined as the position of the apex of the first concentration peak 221. The first concentration peak 221 has a first tail portion 231 where the dopant concentration monotonically decreases from the lower surface 23 toward the upper surface 21.

The second cathode region 82 may have the second concentration peak 222 of a dopant (boron in the present example) in the depth direction. When the dopant concentration in the second cathode region 82 reaches the maximum value at the position of the lower surface 23 of the semiconductor substrate 10, the lower surface 23 may be defined as the position of the apex of the second concentration peak 222. The second concentration peak 222 has a second tail portion 232 where the dopant concentration monotonically decreases from the lower surface 23 toward the upper surface 21. The boron chemical concentration in the second cathode region 82 may decrease continuously from the lower surface 23 to at least the buffer region 20 in the depth direction (Z-axis direction) of the second cathode region 82. “Decreasing continuously” may indicate a monotonic decrease where it decreases monotonically, and may mean a smooth decrease without including a discontinuous portion (discontinuous point). This allows the boron chemical concentration distribution in both the second cathode region 82 and the third cathode region 84 to be formed smoothly. Note that concerning a plurality of measurement points next to each other in SR profiling, SIMS measurement, or the like, the values at the measurement points may be discontinuous. That is, when the measurement points at which measuring apparatuses or the like are discretely arranged are measured, the measurement values may be discrete (discontinuous).

As described above, the second tail portion 232 is provided to extend deeper than the first tail portion 231. A region where the concentration in the second tail portion 232 is higher than the concentration in the first tail portion 231 is the third cathode region 84. According to the present example, the second cathode region 82 and the third cathode region 84 can be formed in the same process, and thus the manufacturing process of the semiconductor device 100 can be simplified. Accordingly, variation in performance of the semiconductor devices 100 can be suppressed, and the manufacturing cost can be reduced.

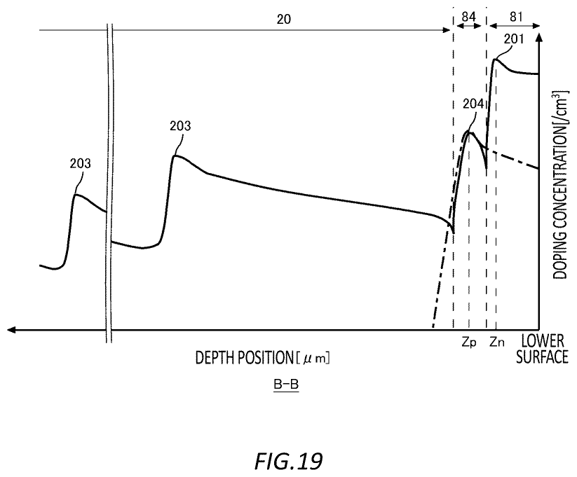

FIG. 19 shows an example of the doping concentration distribution in the line B-B in FIG. 17. The line B-B is a straight line that passes through the first cathode region 81 and the third cathode region 84 and that is parallel to the Z-axis. The semiconductor device 100 of the present example is different from that of the example of FIG. 18 in that the donor, such as phosphorus, and the acceptor, such as boron, are injected to different depth positions.

The first cathode region 81 of the present example has the first concentration peak 201 of the doping concentration in the depth direction. As described above, the first concentration peak of a dopant, such as phosphorus, is provided at the depth position Zn which is the same position as the first concentration peak 201.

The third cathode region 84 of the present example has the third concentration peak 204 of the doping concentration in the depth direction. As described above, the third concentration peak of a dopant, such as boron, is provided at the depth position Zp which is the same position as the third concentration peak 204. The depth position Zp is provided at a deeper position than the depth position Zn. In the present specification, the description of “deep” or “shallow” indicates a position relative to one of the upper surface 21 or the lower surface 23 of the semiconductor substrate 10 which is closer to the position. For example, the depth position Zp arranged on the lower surface 23 side of the semiconductor substrate 10 has a larger distance from the lower surface 23 than the depth position Zn, and thus the depth position Zp is provided deeper than the depth position Zn.

The chemical concentration distribution of boron that forms the third cathode region 84 is shown by a dash-dotted line. The boron chemical concentration distribution in the third cathode region 84 may vary continuously from the lower surface 23 to at least the buffer region 20. “Varying continuously” may indicate a smooth variation without including a discontinuous portion (discontinuous point). Note that concerning a plurality of measurement points next to each other in SR profiling, SIMS measurement, or the like, the values at the measurement points may be discontinuous.

The buffer region 20 may include one or more concentration peaks 203 of the doping concentration in the depth direction. The concentration peaks 203 may be concentration peaks of the hydrogen donor.

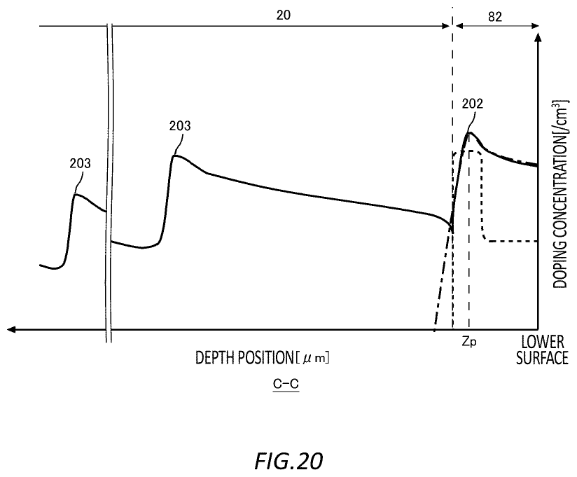

FIG. 20 shows an example of the doping concentration distribution in the line C-C in FIG. 17. The line C-C is a straight line that passes through the second cathode region 82 and that is parallel to the Z-axis. The second cathode region 82 of the present example has the second concentration peak 202 of the doping concentration in the depth direction.

The depth position of the second concentration peak 202 may be the same as the depth position Zp of the third concentration peak 204. In this case, the depth position Zp of the second concentration peak 202 is deeper than the depth position Zn of the first concentration peak 201. Also, the second cathode region 82 and the third cathode region 84 can be manufactured in the same process. The doping concentration distribution of the second cathode region 82 may vary continuously from the lower surface 23 to at least the buffer region 20. “Varying continuously” may indicate a smooth variation without including a discontinuous portion (discontinuous point). For example, the dotted line in FIG. 20 represents a case including a discontinuous point. That is, the discontinuous concentration distribution refers to such a distribution that involves an abrupt increase or decrease in the concentration at a certain depth position, resulting in an extremely large absolute value of the derivative value of the concentration distribution. Note that concerning a plurality of measurement points next to each other in SR profiling, SIMS measurement, or the like, the values at the measurement points may be discontinuous.

In other examples, the depth position of the second concentration peak 202 may be different from the depth position Zp of the third concentration peak 204. In this case, the second cathode region 82 and the third cathode region 84 are formed in different processes. The second cathode region 82 and the third cathode region 84 may each be formed by selectively injecting a dopant, such as boron, in the plane X-Y. In this case, the position and the thickness of the third cathode region 84 in the depth direction can be set independently of the position and the thickness of the second cathode region 82.

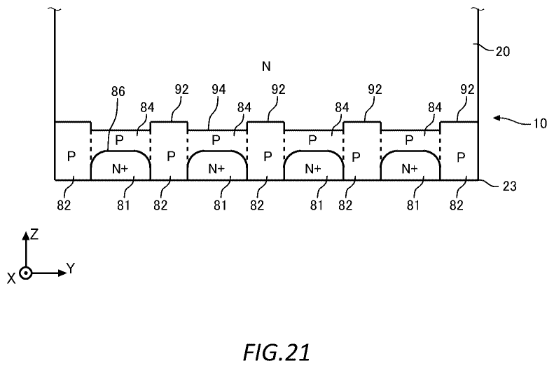

FIG. 21 shows another example of the cross-section Y-Z. In the present example, the position of the upper surface 92 of the second cathode region 82 and the position of the upper surface 94 of the third cathode region 84 in the depth direction of the semiconductor substrate 10 are different from each other. Other structures are similar to those in any of the examples described herein. As described above, in the present example, the second cathode region 82 and the third cathode region 84 may be formed in the different processes by injecting a dopant to the different depth positions.

In the example of FIG. 21, the position of the upper surface 92 of the second cathode region 82 is deeper than the position of the upper surface 94 of the third cathode region 84. This allows the reduction of the thickness of the third cathode region 84 in the depth direction. By the reduction of the thickness of the third cathode region 84, injection of carriers from the first cathode region 81 can be promoted, and the waveform oscillation during switching operation can be suppressed. In particular, injection of carriers when the diode portion 80 is turned on can be promoted, and the peak voltage in the transient waveform of the forward voltage can be reduced.

The thickness of the third cathode region 84 may be less than one time the thickness of the first cathode region 81, may be 0.5 times or less, or 0.25 times or less the thickness of the first cathode region 81. Even in other examples described herein, the relationship between the thickness of the third cathode region 84 and the thickness of the first cathode region 81 may be similar to the present example. A thickness in the center of each region in the Y-axis direction may be used as the thickness in each region.

A distance between the upper surface 92 and the upper surface 94 in the depth direction may be 0.1 times or more, 0.2 times or more, or 0.5 times or more the thickness of the third cathode region 84. The distance may be twice or less, or one time or less the thickness of the third cathode region 84.

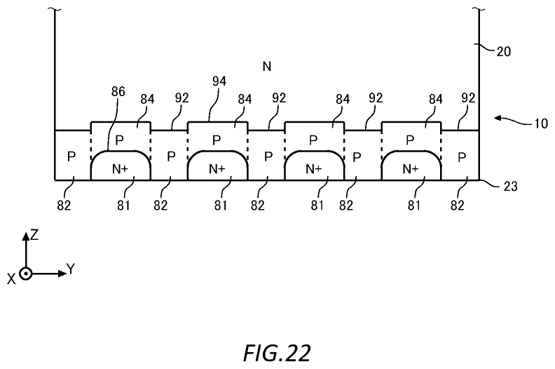

FIG. 22 shows another example of the cross-section Y-Z. In the present example, the position of the upper surface 92 of the second cathode region 82 is shallower than the position of the upper surface 94 of the third cathode region 84. Except for that, this example has a structure similar to the one in the example shown in FIG. 21. By setting the third cathode region 84 to be deeper, positive holes above the first cathode region 81 can be extracted more easily. Also, when the diode portion 80 is in an ON-state, positive holes above the upper surface 94 move along the upper surface 94 and reach the second cathode region 82 to be extracted easily to the collector electrode 24.

The thickness of the third cathode region 84 may be 0.25 times or more, 0.5 times or more, or one time or more the thickness of the first cathode region 81. The thickness of the third cathode region 84 may be twice or less, or 1.5 times or less the thickness of the first cathode region 81.

A distance between the upper surface 92 and the upper surface 94 in the depth direction may be 0.1 times or more, 0.2 times or more, or 0.5 times or more the thickness of the third cathode region 84. The distance may be twice or less, or one time or less the thickness of the third cathode region 84.

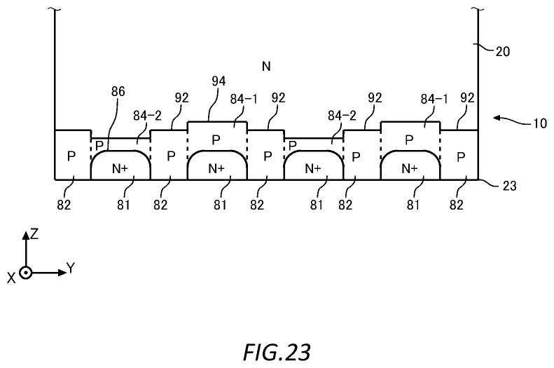

FIG. 23 shows another example of the cross-section Y-Z. In the present example, the position of the upper surfaces 94 of some third cathode regions 84-1 is deeper than the position of the upper surfaces 94 of some other third cathode regions 84-2. Other structures are similar to those in any of the examples described herein.

In the present example, the position of the upper surface 94 of the third cathode region 84-2 is shallower than the position of the upper surface 92 of the second cathode region 82. Also, the position of the upper surface 94 of the third cathode region 84-1 is deeper than the position of the upper surface 92 of the second cathode region 82. In the Y-axis direction, the third cathode region 84-1 and the third cathode region 84-2 may be alternately arranged. The second cathode region 82 is arranged between the third cathode region 84-1 and the third cathode region 84-2.

With such a configuration, the effect described in the example of FIG. 21 and the effect described in the example of FIG. 22 can be obtained. In the Y-axis direction, the width of the third cathode region 84-1 may be smaller than, may be larger than, or may be the same as the width of the third cathode region 84-2. The structures, such as the thickness, of the third cathode region 84-1 may be similar to those in the example of FIG. 22. The structures, such as the thickness, of the third cathode region 84-2 may be similar to those in the example of FIG. 21.

The thickness of the third cathode region 84-1 in the depth direction may be different from the thickness of another third cathode region 84-2 in the depth direction. In the example of FIG. 23, the thickness of the third cathode region 84-1 is larger than the thickness of the third cathode region 84-2. In other examples, the thickness of the third cathode region 84-1 may be the same as the thickness of the third cathode region 84-2. In this case, the thickness of the first cathode region 81 below the third cathode region 84-1 may be larger than the thickness of the first cathode region 81 below the third cathode region 84-2. This allows the position of the upper surface 94 of the third cathode region 84-1 to be deeper than the position of the upper surface 94 of the third cathode region 84-2.

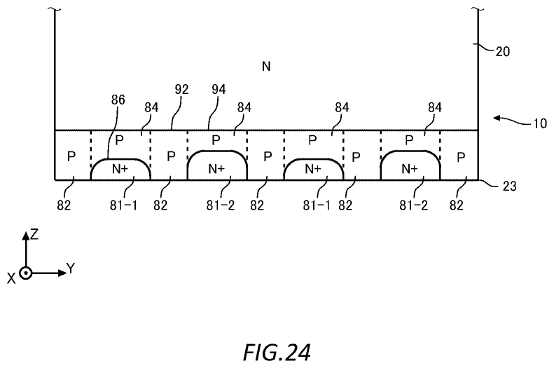

FIG. 24 shows another example of the cross-section Y-Z. In the present example, the thickness of the first cathode region 81-1 in the depth direction is different from the thickness of another first cathode region 81-2 in the depth direction. Other structures are similar to those in any of the examples described herein.

In the present example, the thickness of the first cathode region 81-1 is smaller than the thickness of the first cathode region 81-2. The first cathode region 81-1 and the first cathode region 81-2 may be alternately arranged in the Y-axis direction. The upper surface 94 of the third cathode region 84 above the first cathode region 81-1 may be provided at the same depth position as the upper surface 94 of the third cathode region 84 above the first cathode region 81-2. In this case, the third cathode region 84 above the first cathode region 81-1 is thicker than the third cathode region 84 above the first cathode region 81-2. With such a configuration as well, an effect similar to that of the example in FIG. 23 can be obtained.

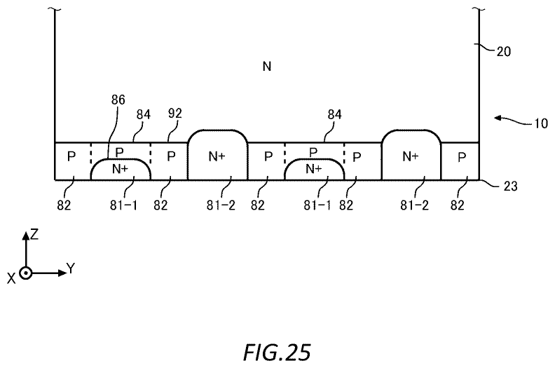

FIG. 25 shows another example of the cross-section Y-Z. In the present example, the third cathode region 84 is provided in contact with the upper surface 86 of at least one first cathode region 81-1. Also, no third cathode region 84 is provided on the upper surface 86 of at least one first cathode region 81-2. The position of the upper surface 86 of the first cathode region 81-2 is deeper than the position of the upper surface 94 of the third cathode region 84. Other structures are similar to those in any of the examples described herein. With such a configuration as well, an effect similar to that of the example in FIG. 23 can be obtained.

The upper surface 86 of the first cathode region 81-2 may be arranged deeper than the upper surface 92 of the second cathode region 82. The upper surface 86 of the first cathode region 81-2 of the present example is in contact with the buffer region 20 or the drift region 18.

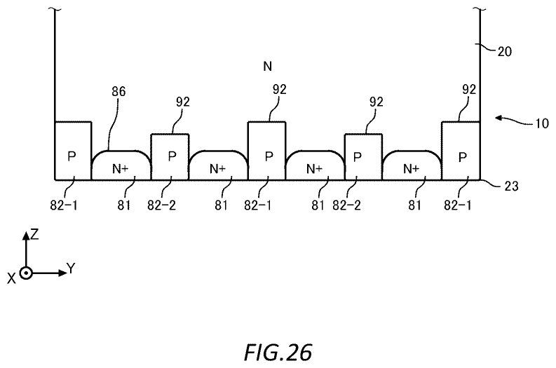

FIG. 26 shows another example of the cross-section Y-Z. In the present example, the position of the upper surface 92 of each of the second cathode regions 82 is deeper than the position of the upper surface 86 of the first cathode region 81. Also, the position of the upper surface 92 of any of the second cathode regions 82-1 is deeper than the position of the upper surface 92 of any other of the second cathode regions 82-2. In the present example, no third cathode region 84 is provided. According to the present example, the ease of positive hole extraction can be adjusted by the position in the Y-axis direction.

In the plurality of second cathode regions 82, the width, in the Y-axis direction, of the second cathode region 82-1 of which the upper surface 92 is provided in the deepest position may be larger than the width, in the Y-axis direction, of any other of the second cathode regions 82-2. This can further promote the extraction of positive holes.

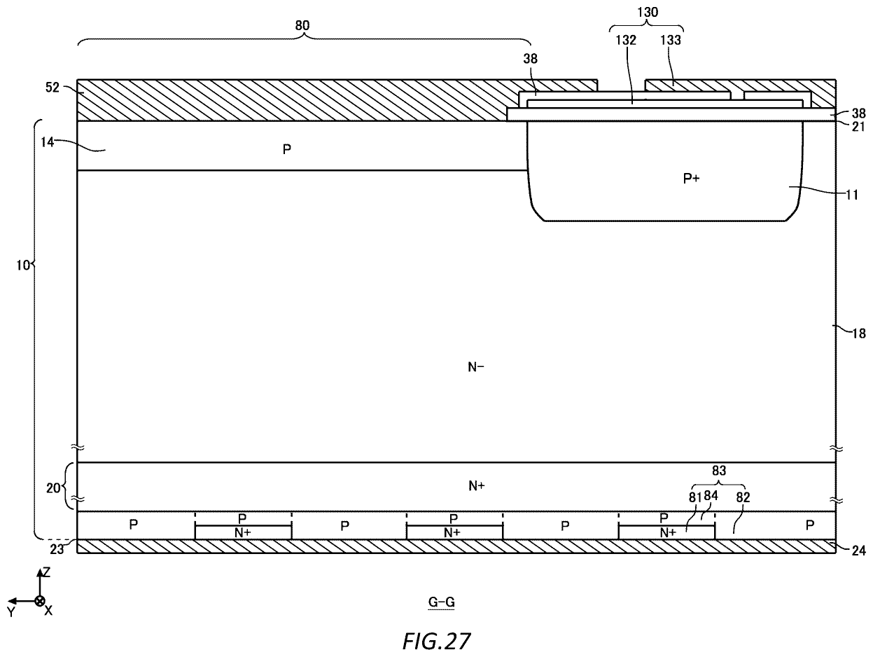

FIG. 27 shows an example of the cross-section G-G in FIG. 1. The cross-section G-G is a cross-section Y-Z that passes through the diode portion 80 and the outer circumferential gate runner 130. The outer circumferential gate runner 130 in the present example includes semiconductor wiring 132 and metal wiring 133. For example, the semiconductor wiring 132 is formed of a semiconductor, such as polysilicon, in which impurity is added. For example, the metal wiring 133 is formed of metal, such as aluminum.

The metal wiring 133 is arranged outside relative to the emitter electrode 52. The semiconductor wiring 132 is arranged below the metal wiring 133 so that a part or all of the semiconductor wiring 132 overlaps with the metal wiring 133. The semiconductor wiring 132 of the present example also extends below the emitter electrode 52. An interlayer dielectric film 38 is provided between the semiconductor wiring 132 and the metal wiring 133 and emitter electrode 52. In addition, the interlayer dielectric film 38 is also provided between the semiconductor wiring 132 and metal wiring 133 and the semiconductor substrate 10. The semiconductor wiring 132 and the metal wiring 133 are electrically connected via a contact hole provided in the interlayer dielectric film 38.

A well region 11 is provided in the semiconductor substrate 10 below the outer circumferential gate runner 130. The well region 11 is in contact with the upper surface 21 of the semiconductor substrate 10, and formed to extend deeper than the base region 14. The well region 11 may have a higher doping concentration than that of the base region 14. The well region 11 may be provided so as to overlap with the entire semiconductor wiring 132.

The cathode region 83 may be provided from the diode portion 80 to a region below the well region 11. The cathode region 83 may extend to outside the well region 11. At least one first cathode region 81 may be provided outside the well region 11. At least one second cathode region 82 may be provided outside the well region 11. At least one third cathode region 84 may be provided outside the well region 11. The cathode region 83 is similar to those in any of the examples described herein. The cathode region 83 in FIG. 27 includes the first cathode region 81, the second cathode region 82, and the third cathode region 84. According to the present example, positive holes injected from the well region 11 can be efficiently extracted.

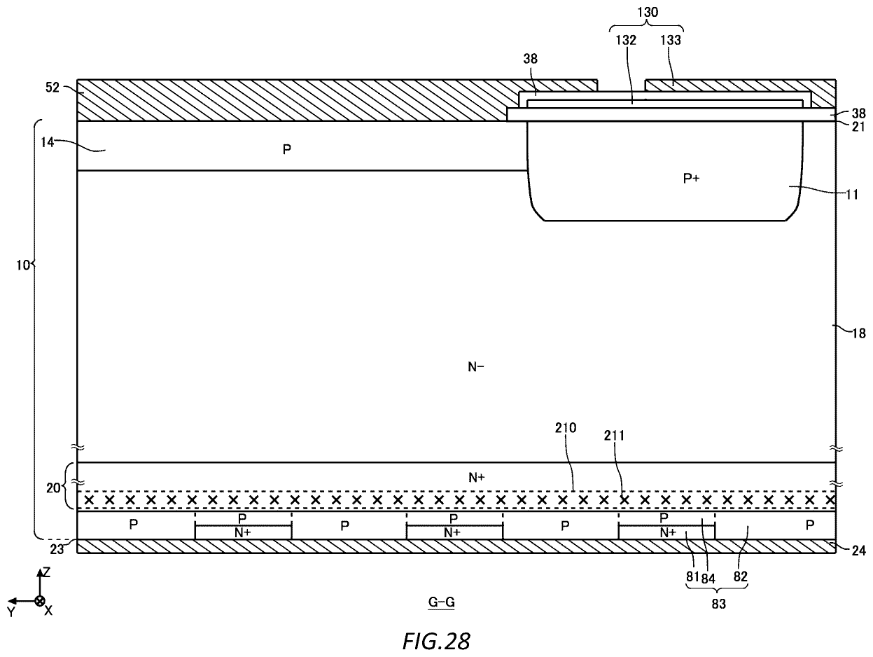

FIG. 28 shows another example of the cross-section G-G. The semiconductor device 100 of the present example is different from those in other examples described herein in that it is provided on the lower surface 23 side of the semiconductor substrate 10 and that it includes a lifetime adjustment region 210 where the carrier lifetime exhibits a minimum value. Other structures are similar to those in any of the examples described herein.

The lifetime adjustment region 210 can be formed by injecting charged particles, such as helium, into the semiconductor substrate 10. By injecting the charged particles into the semiconductor substrate 10, recombination centers 211 of the carriers can be formed in this place, allowing reduction of the carrier lifetime.

The lifetime adjustment region 210 is provided in at least part of the diode portion 80. The lifetime adjustment region 210 may be provided in the entire diode portion 80 in a top view. The lifetime adjustment region 210 may extend to a region below the well region 11, or may extend to outside the well region 11.

The third cathode region 84 is arranged between the lifetime adjustment region 210 and the lower surface 23. The lifetime adjustment region 210 of the present example is provided in the buffer region 20. The second cathode region 82 may also be arranged between the lifetime adjustment region 210 and the lower surface 23. According to the present example, at the time of turn-off of the diode portion 80, the lifetime of the positive holes can be shortened, and thus the reverse recovery loss Err can further be reduced.

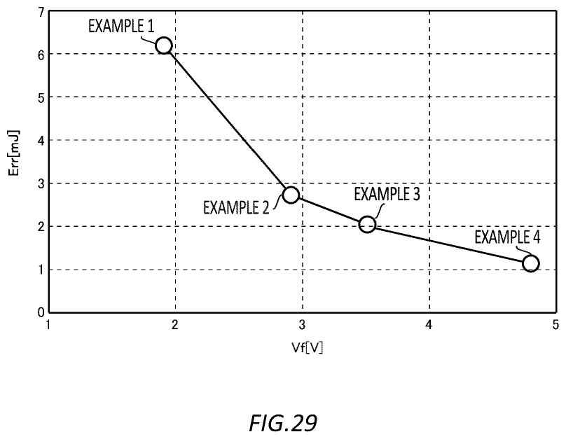

FIG. 29 shows a relationship between the forward voltage Vf and the reverse recovery loss Err of the diode portion 80. FIG. 29 shows the relationship between the forward voltage Vf and the reverse recovery loss Err in the semiconductor devices according to examples 1, 2, 3, and 4. The examples 1 to 3 are an example in which no lifetime adjustment region 210 is provided, whereas the example 4 is an example in which the lifetime adjustment region 210 is provided. Also, the example 1 is an example in which the first cathode region 81 is provided, but the second cathode region 82 and the third cathode region 84 are not provided. The example 2 is an example in which the first cathode region 81 and the second cathode region 82 are provided, but the third cathode region 84 is not provided. The examples 3 and 4 are examples in which the first cathode region 81, the second cathode region 82, and third cathode region 84 are provided.

As shown in FIG. 29, by providing the second cathode region 82, the reverse recovery loss Err can be reduced. Also, by providing the third cathode region 84, the reverse recovery loss Err can be further reduced. Also, by providing the lifetime adjustment region 210, the reverse recovery loss Err can be further reduced.

Each of the following items is also disclosed in the present invention.

### (Item 1)

A semiconductor device comprising a semiconductor substrate which has an upper surface and a lower surface and which is provided with a diode portion including a longitudinal length in a first direction, wherein
the diode portion includes
a drift region of a first conductivity type provided on the semiconductor substrate,
a first cathode region of a first conductivity type which is provided in contact with the lower surface of the semiconductor substrate and which has a doping concentration higher than that of the drift region, and
a second cathode region of a second conductivity type provided in contact with the lower surface of the semiconductor substrate, wherein
the first cathode region and the second cathode region are provided alternately in the first direction,
one or more first cathode regions, each being identical to the first cathode region, are provided on the lower surface of the semiconductor substrate in a second direction that intersects the first direction, and
a length Lx between both ends of the one or more first cathode regions in the second direction and a width Dyn of one first cathode region, identical to the first cathode region, in the first direction satisfy a following expression:

$$0.001 < Dyn / Lx \leq 0.1 .$$

### (Item 2)

The semiconductor device according to item 1, wherein
a total area Sn of the one or more first cathode regions and a total area Sp of one or more second cathode regions, each being identical to the second cathode region, on the lower surface satisfy a following expression:

$$0.1 \leq Sn / ( Sn + S p ) < 1 .$$

### (Item 3)

The semiconductor device according to item 2, wherein
the total area Sn and the total area Sp satisfy a following expression:

$$0.4 \leq Sn / ( Sn + S p ) < 0.8 .$$

### (Item 4)

The semiconductor device according to item 2, wherein
the total area Sn and the total area Sp satisfy a following expression:

$$0.5 \leq Sn / ( Sn + S p ) < 0.75 .$$

### (Item 5)

The semiconductor device according to item 1, wherein
a width Dyp of one second cathode region, identical to the second cathode region, in the first direction and a width Dyn of one first cathode region, identical to the first cathode region, in the first direction satisfy a following expression:

$$0.1 \leq Dyn / ( Dyn + D y p ) < 1 .$$

### (Item 6)

The semiconductor device according to item 5, wherein
the width Dyp and the width Dyn satisfy a following expression:

$$0.4 \leq Dyn / ( Dyn + D y p ) < 0.8 .$$

### (Item 7)

The semiconductor device according to item 5, wherein
the width Dyp and the width Dyn satisfy a following expression:

$$0.5 \leq Dyn / ( Dyn + D y p ) < 0.75 .$$

### (Item 8)

The semiconductor device according to item 1, wherein
a width Dyn of one first cathode region, identical to the first cathode region, in the first direction is larger than a width Dyp of one second cathode region, identical to the second cathode region, in the first direction.

### (Item 9)

A semiconductor device comprising a semiconductor substrate which has an upper surface and a lower surface and which is provided with a diode portion including a longitudinal length in a first direction, wherein
the diode portion includes
a drift region of a first conductivity type provided on the semiconductor substrate,
a first cathode region of a first conductivity type which is provided in contact with the lower surface of the semiconductor substrate and which has a doping concentration higher than that of the drift region, and
a second cathode region of a second conductivity type provided in contact with the lower surface of the semiconductor substrate, wherein
the first cathode region and the second cathode region are provided alternately in the first direction,
one or more first cathode regions, each being identical to the first cathode region, are provided on the lower surface of the semiconductor substrate in a second direction that intersects the first direction, and
a length Lx between both ends of the one or more first cathode regions in the second direction and a width Dyn of one first cathode region, identical to the first cathode region, in the first direction satisfy a following expression:

$$0.001 < Dyn / Lx \leq 0.4 ,$$

and
a total area Sn of the one or more first cathode regions and a total area Sp of one or more second cathode regions, each being identical to the second cathode region, on the lower surface satisfy a following expression:

$$0.5 \leq Sn / ( Sn + S p ) < 0.75 .$$

### (Item 10)

The semiconductor device according to any one of items 1 to 9, wherein
the one or more first cathode regions are discretely arranged in both the first direction and the second direction, and
a space between the first cathode regions in a center of the diode portion in the second direction is smaller than a space between the first cathode regions in an end portion of the diode portion in the second direction.

### (Item 11)

The semiconductor device according to item 10, wherein
a width Dxn of one first cathode region, identical to the first cathode region, in the second direction in a center of the diode portion in the second direction is smaller than a width Dxn of one first cathode region, identical to the first cathode region, in the second direction in an end portion of the diode portion in the second direction.

### (Item 12)

The semiconductor device according to item 11, wherein
in one first cathode region, identical to the first cathode region, arranged in an end portion of the diode portion in the second direction, a width in the second direction is larger than a width in the first direction.

### (Item 13)

The semiconductor device according to any one of items 1 to 9, wherein
a width of one second cathode region, identical to the second cathode region, in the first direction is larger than a width of the first cathode region in a depth direction of the semiconductor substrate.

### (Item 14)

The semiconductor device according to any one of items 1 to 9, wherein
a width of one second cathode region, identical to the second cathode region, in the first direction is larger than a width of the second cathode region in a depth direction of the semiconductor substrate.

### (Item 15)

The semiconductor device according to any one of items 1 to 9, wherein
an upper surface of the first cathode region in a depth direction includes a flat portion that has a uniform distance to the lower surface of the semiconductor substrate, and
a distance between flat portions, each being identical to the flat portion, of two first cathode regions, each being identical to the first cathode region, that are next to each other in the first direction is larger than 1.6 times a distance between the flat portion and the lower surface.

### (Item 16)

The semiconductor device according to any one of items 1 to 9, wherein
on the lower surface of the semiconductor substrate, the first cathode region includes a first end side that is straight and a second end side that is straight and has a gradient relative to the first end side, and the first end side and the second end side are connected by a curved line.

### (Item 17)

The semiconductor device according to item 16, wherein
a width Dyp of one second cathode region, identical to the second cathode region, in the first direction is smaller than a radius of curvature of the curved line.

### (Item 18)

The semiconductor device according to any one of items 1 to 9, wherein
the semiconductor substrate is provided with a transistor portion, the transistor portion and the diode portion are alternately arranged in the second direction, and
the transistor portion includes a plurality of gate trench portions each of which includes a longitudinal length in the first direction on the upper surface of the semiconductor substrate.

### (Item 19)

The semiconductor device according to any one of items 1 to 9, further comprising:
a third cathode region of a second conductivity type provided in contact with an upper surface of the first cathode region.

### (Item 20)

The semiconductor device according to item 19, wherein
the third cathode region is connected to the second cathode region.

### (Item 21)

The semiconductor device according to item 20, wherein
the first cathode region is sandwiched by two second cathode regions, each being identical to the second cathode region, in a direction parallel to the lower surface of the semiconductor substrate, and
the third cathode region is connected to the two second cathode regions that sandwich the first cathode region.

### (Item 22)

The semiconductor device according to item 19, wherein
a position of an upper surface of the second cathode region and a position of an upper surface of the third cathode region are different from each other in a depth direction of the semiconductor substrate.

### (Item 23)

The semiconductor device according to any one of items 1 to 9, wherein
the diode portion includes a plurality of first cathode regions, each being identical to the first cathode region, and
a thickness of any of the plurality of first cathode regions in a depth direction is different from a thickness of any other of the plurality of first cathode regions in the depth direction.

### (Item 24)

The semiconductor device according to item 23, further comprising:
a third cathode region of a second conductivity type provided in contact with an upper surface of each of the plurality of first cathode regions.

### (Item 25)

The semiconductor device according to item 23, further comprising:
a third cathode region of a second conductivity type provided in contact with an upper surface of at least one of the plurality of first cathode regions, wherein
the third cathode region is not provided on an upper surface of at least one of the plurality of first cathode regions, and
a position of the upper surface of the first cathode region on which the third cathode region is not provided is deeper than a position of an upper surface of the third cathode region.

### (Item 26)

The semiconductor device according to any one of items 1 to 9, wherein
a position of an upper surface of each of the one or more second cathode regions is deeper than a position of an upper surface of the first cathode region, and
a position of an upper surface of any of the one or more second cathode regions is deeper than a position of an upper surface of any other of the one or more second cathode regions.

### (Item 27)

The semiconductor device according to item 26, wherein
among a plurality of second cathode regions, each being identical to the second cathode region, a width, in the first direction, of the second cathode region of which the upper surface is provided in a deepest position is larger than a width, in the first direction, of any other of the plurality of second cathode regions.

### (Item 28)

The semiconductor device according to item 19, further comprising:
a lifetime adjustment region which is provided on the lower surface side of the semiconductor substrate and in which a carrier lifetime exhibits a minimum value, wherein
the third cathode region is arranged between the lifetime adjustment region and the lower surface.

### (Item 29)

A semiconductor device comprising a semiconductor substrate which has an upper surface and a lower surface and which is provided with a diode portion including a longitudinal length in a first direction, wherein
the diode portion includes
a drift region of a first conductivity type provided on the semiconductor substrate,
a first cathode region of a first conductivity type which is provided in contact with the lower surface of the semiconductor substrate and which has a doping concentration higher than that of the drift region,
a second cathode region of a second conductivity type provided in contact with the lower surface of the semiconductor substrate, and
a third cathode region of a second conductivity type provided in contact with an upper surface of the first cathode region, wherein
a position of an upper surface of the second cathode region and a position of an upper surface of the third cathode region are different from each other in a depth direction of the semiconductor substrate.

### (Item 30)

The semiconductor device according to item 29, wherein
a position of the upper surface of the second cathode region is deeper than a position of the upper surface of the third cathode region.

### (Item 31)

The semiconductor device according to item 29, wherein
a position of the upper surface of the second cathode region is shallower than a position of the upper surface of the third cathode region.

### (Item 32)

The semiconductor device according to item 29, wherein
a position of the upper surface of each of some third cathode regions, each being identical to the third cathode region, is shallower than a position of the upper surface of the second cathode region, and a position of the upper surface of each of some other third cathode regions, each being identical to the third cathode region, is deeper than a position of the upper surface of the second cathode region.

### (Item 33)

The semiconductor device according to item 32, wherein
the diode portion includes a plurality of first cathode regions, each being identical to the first cathode region, and a plurality of third cathode regions, each being identical to the third cathode region, and
a thickness of any of the plurality of third cathode regions in the depth direction is different from a thickness of any other of the plurality of third cathode regions in the depth direction.

### (Item 34)

The semiconductor device according to any one of items 29 to 33, wherein
the first cathode region has a first concentration peak of a dopant in the depth direction,
the second cathode region has a second concentration peak of a dopant in the depth direction, and
the second concentration peak is provided in a position deeper than the first concentration peak.

### (Item 35)

The semiconductor device according to any one of items 29 to 33, wherein
the first cathode region has a first concentration peak of a dopant in the depth direction,
the second cathode region has a second concentration peak of a dopant in the depth direction,
the first concentration peak includes a first tail portion where a concentration monotonically decreases toward an upper surface of the semiconductor substrate,
the second concentration peak includes a second tail portion where a concentration monotonically decreases toward an upper surface of the semiconductor substrate, and
the second tail portion is provided to extend deeper than the first tail portion.

### (Item 36)

A semiconductor device comprising a semiconductor substrate which has an upper surface and a lower surface and which is provided with a diode portion including a longitudinal length in a first direction, wherein
the diode portion includes
a drift region of a first conductivity type provided on the semiconductor substrate,
a first cathode region of a first conductivity type which is provided in contact with the lower surface of the semiconductor substrate and which has a doping concentration higher than that of the drift region,
a second cathode region of a second conductivity type provided in contact with the lower surface of the semiconductor substrate, and
a third cathode region of a second conductivity type which is in contact with the first cathode region in a depth direction from the lower surface toward the upper surface of the semiconductor substrate and which is in contact with the second cathode region in a direction parallel to the lower surface, wherein
the first cathode region and the second cathode region are provided alternately in the first direction.

### (Item 37)

The semiconductor device according to item 36, wherein
a maximum depth of the third cathode region, from the lower surface, that is in contact with the first cathode region is substantially the same as a maximum depth of the second cathode region from the lower surface.

### (Item 38)

The semiconductor device according to item 36, wherein
a chemical concentration distribution of an acceptor of the second cathode region is smooth without including a discontinuous point.

While the present invention has been described above by way of the embodiments, the technical scope of the present invention is not limited to the scope described in the above-described embodiments. It is apparent to persons skilled in the art that various alterations or improvements can be made to the above-described embodiments. It is also apparent from the description of the claims that the embodiments to which such alterations or improvements are made can fall within the technical scope of the present invention.

Each process of the operations, procedures, steps, stages, and the like performed by a device, system, program, and method shown in the claims, the specification, and the drawings can be performed in any order as long as the order is not indicated by “prior to,” “before,” and the like and as long as the output from a previous process is not used in a later process. Even if the operational flow is described using phrases such as “first” or “next” for convenience in the claims, the specification, and the drawings, it does not necessarily mean that the process must be performed in this order.

What is claimed is:

1. A semiconductor device comprising a semiconductor substrate which has an upper surface and a lower surface and which is provided with a diode portion including a longitudinal length in a first direction, wherein
the diode portion includes:
a drift region of a first conductivity type provided on the semiconductor substrate,
a first cathode region of a first conductivity type which is provided in contact with the lower surface of the semiconductor substrate and which has a doping concentration higher than that of the drift region, and
a second cathode region of a second conductivity type provided in contact with the lower surface of the semiconductor substrate, wherein
the first cathode region and the second cathode region are provided alternately in the first direction,
one or more first cathode regions, each being identical to the first cathode region, are provided on the lower surface of the semiconductor substrate in a second direction that intersects the first direction, and
a length Lx between both ends of the one or more first cathode regions in the second direction and a width Dyn of one first cathode region, identical to the first cathode region, in the first direction satisfy a following expression:
$$0.001 < Dyn / Lx \leq 0.1 .$$

2. The semiconductor device according to claim 1, wherein
a total area Sn of the one or more first cathode regions and a total area Sp of one or more second cathode regions, each being identical to the second cathode region, on the lower surface satisfy a following expression:
$$0.1 \leq Sn / ( Sn + S p ) < 1 .$$

3. The semiconductor device according to claim 1, wherein
a width Dyp of one second cathode region, identical to the second cathode region, in the first direction and a width Dyn of one first cathode region, identical to the first cathode region, in the first direction satisfy a following expression:
$$0.1 \leq Dyn / ( Dyn + D y p ) < 1 .$$

4. The semiconductor device according to claim 1, wherein
a width Dyn of one first cathode region, identical to the first cathode region, in the first direction is larger than a width Dyp of one second cathode region, identical to the second cathode region, in the first direction.

5. A semiconductor device comprising a semiconductor substrate which has an upper surface and a lower surface and which is provided with a diode portion including a longitudinal length in a first direction, wherein
the diode portion includes:
a drift region of a first conductivity type provided on the semiconductor substrate,
a first cathode region of a first conductivity type which is provided in contact with the lower surface of the semiconductor substrate and which has a doping concentration higher than that of the drift region, and
a second cathode region of a second conductivity type provided in contact with the lower surface of the semiconductor substrate, wherein
the first cathode region and the second cathode region are provided alternately in the first direction,
one or more first cathode regions, each being identical to the first cathode region, are provided on the lower surface of the semiconductor substrate in a second direction that intersects the first direction, and
a length Lx between both ends of the one or more first cathode regions in the second direction and a width Dyn of one first cathode region, identical to the first cathode region, in the first direction satisfy a following expression:
$$0.001 < Dyn / Lx \leq 0.4 ,$$
a total area Sn of the one or more first cathode regions and a total area Sp of one or more second cathode regions, each being identical to the second cathode region, on the lower surface satisfy a following expression:
$$0.5 \leq Sn / ( Sn + S p ) < 0.75 .$$

6. The semiconductor device according to claim 5, wherein
the one or more first cathode regions are discretely arranged in both the first direction and the second direction, and
a space between the first cathode regions in a center of the diode portion in the second direction is smaller than a space between the first cathode regions in an end portion of the diode portion in the second direction.

7. The semiconductor device according to claim 5, wherein
a width of one second cathode region, identical to the second cathode region, in the first direction is larger than a width of the first cathode region in a depth direction of the semiconductor substrate.

8. The semiconductor device according to claim 5, wherein
a width of one second cathode region, identical to the second cathode region, in the first direction is larger than a width of the second cathode region in a depth direction of the semiconductor substrate.

9. The semiconductor device according to claim 5, wherein
an upper surface of the first cathode region in a depth direction includes a flat portion that has a uniform distance to the lower surface of the semiconductor substrate, and
a distance between flat portions, each being identical to the flat portion, of two first cathode regions, each being identical to the first cathode region, that are next to each other in the first direction is larger than 1.6 times a distance between the flat portion and the lower surface.

10. The semiconductor device according to claim 5, wherein
on the lower surface of the semiconductor substrate, the first cathode region includes a first end side that is straight and a second end side that is straight and has a gradient relative to the first end side, and the first end side and the second end side are connected by a curved line.

11. The semiconductor device according to claim 5, wherein
the semiconductor substrate is provided with a transistor portion, the transistor portion and the diode portion are alternately arranged in the second direction, and
the transistor portion includes a plurality of gate trench portions each of which includes a longitudinal length in the first direction on the upper surface of the semiconductor substrate.

12. The semiconductor device according to claim 5, further comprising:
a third cathode region of a second conductivity type provided in contact with an upper surface of the first cathode region.

13. The semiconductor device according to claim 5, wherein
the diode portion includes a plurality of first cathode regions, each being identical to the first cathode region, and
a thickness of any of the plurality of first cathode regions in a depth direction is different from a thickness of any other of the plurality of first cathode regions in the depth direction.

14. The semiconductor device according to claim 5, wherein
a position of an upper surface of each of the one or more second cathode regions is deeper than a position of an upper surface of the first cathode region, and
a position of an upper surface of any of the one or more second cathode regions is deeper than a position of an upper surface of any other of the one or more second cathode regions.

15. A semiconductor device comprising a semiconductor substrate which has an upper surface and a lower surface and which is provided with a diode portion including a longitudinal length in a first direction, wherein
the diode portion includes:
a drift region of a first conductivity type provided on the semiconductor substrate,
a first cathode region of a first conductivity type which is provided in contact with the lower surface of the semiconductor substrate and which has a doping concentration higher than that of the drift region,
a second cathode region of a second conductivity type provided in contact with the lower surface of the semiconductor substrate, and
a third cathode region of a second conductivity type provided in contact with an upper surface of the first cathode region, wherein
a position of an upper surface of the second cathode region and a position of an upper surface of the third cathode region are different from each other in a depth direction of the semiconductor substrate.

16. The semiconductor device according to claim 15, wherein
a position of the upper surface of the second cathode region is deeper than a position of the upper surface of the third cathode region.

17. The semiconductor device according to claim 15, wherein
a position of the upper surface of the second cathode region is shallower than a position of the upper surface of the third cathode region.

18. The semiconductor device according to claim 15, wherein
a position of the upper surface of each of some third cathode regions, each being identical to the third cathode region, is shallower than a position of the upper surface of the second cathode region, and a position of the upper surface of each of some other third cathode regions, each being identical to the third cathode region, is deeper than a position of the upper surface of the second cathode region.

19. The semiconductor device according to claim 15, wherein
the first cathode region has a first concentration peak of a dopant in the depth direction,
the second cathode region has a second concentration peak of a dopant in the depth direction, and
the second concentration peak is provided in a position deeper than the first concentration peak.

20. The semiconductor device according to claim 15, wherein
the first cathode region has a first concentration peak of a dopant in the depth direction,
the second cathode region has a second concentration peak of a dopant in the depth direction,
the first concentration peak includes a first tail portion where a concentration monotonically decreases toward an upper surface of the semiconductor substrate,
the second concentration peak includes a second tail portion where a concentration monotonically decreases toward an upper surface of the semiconductor substrate, and
the second tail portion is provided to extend deeper than the first tail portion.
